(19) United States
(12) Patent Application Publication
(10) Pub. No.: US 2016/0218077 A1
(43) Pub. Date: Jul. 28, 2016

(54) Composite Sheet for Resin Film Formation

(71) Applicant: LINTEC CORPORATION, Tokyo (JP)

(72) Inventors: Yuichiro Azuma, Tokyo (JP); Sayaka Tsuchiyama, Tokyo (JP); Akio Kabuto, Tokyo (JP)

(73) Assignee: LINTEC Corporation, Tokyo (JP)

(21) Appl. No.: 15/023,702

(22) PCT Filed: Sep. 29, 2014
(86) PCT No.: PCT/JP2014/075944

§ 371 Date: Mar. 22, 2016

(30) Foreign Application Priority Data
Sep. 30, 2013 (JP) 2013-205277

(51) Int. Cl. H01L 23/00; H01L 23/29; H01L 23/31

(52) U.S. Cl. CPC H01L 24/29; H01L 23/3142; H01L 23/295; H01L 2224/2919; H01L 2224/29083; H01L 2924/0635; H01L 2924/2064; H01L 2924/20641; H01L 2924/20642; H01L 2924/20643

(57) ABSTRACT

The present invention relates to a composite sheet for resin film formation composed of a pressure-sensitive adhesive sheet having a pressure-sensitive adhesive layer on a base and a heat curable film for resin film formation provided on the pressure-sensitive adhesive layer. The film for resin film formation includes a binder component having a reactive double bond group. The pressure-sensitive adhesive layer includes a non-energy ray curable pressure-sensitive adhesive composition or a cured product of an energy ray curable pressure-sensitive adhesive composition.

### TECHNICAL FIELD

The present invention relates to a composite sheet for resin film formation capable of efficiently forming a resin film having a high adhering strength to a chip and of manufacturing a semiconductor device having a high reliability.

### DESCRIPTION OF THE RELATED ART

Recently, the production of a semiconductor device is carried out by the mounting method of so called “face down method”. In the face down method, the semiconductor chip (hereinafter, it will be simply referred as “chip”) having the electrode such as bumps or so on the circuit face is used, and the electrode is bonded to the substrate. Therefore, the opposite face (the chip backside) of the circuit face of the chip will be exposed.

This chip backside being exposed may be protected by the organic film in some cases. Conventionally, for the chip having the protective film made of this organic film, a liquid resin is coated to the wafer backside by a spin coat method, then dried and cured, and it is obtained by cutting the protective film with the wafer. However, the accuracy of the protective film thickness formed as such is not sufficient, thus the product yield may decline in some cases.

In order to solve the above problem, a dicing tape integrated semiconductor backside film having a flip-chip semiconductor backside film on a pressure-sensitive adhesive layer of the dicing tape including the pressure-sensitive adhesive layer on a base is disclosed (the patent document 1). The flip-chip semiconductor backside film functions as the protective film of the backside of the chip. The pressure-sensitive adhesive layer of the dicing tape integrated semiconductor backside film is radiation ray curable type, and a pressure-sensitive adhesive force of the dicing tape declines by radiation ray irradiation. According to the dicing tape integrated semiconductor backside film of patent document 1, the flip-chip semiconductor backside film and the pressure-sensitive adhesive layer is moderately temporarily adhered when the flip-chip semiconductor backside film is fixed to a semiconductor wafer. Thus, release between the flip-chip semiconductor backside film and the pressure-sensitive adhesive layer due to impact of blade during dicing is suppressed and a falling of chip tends to be prevented. In addition, the pressure-sensitive adhesive layer is mounted on the base, and that cutting chips of the base tends to be suppressed resulting from a decline in base cutting amount by the blade.

The present inventors, on the other hand, disclose an adhesive sheet having an adhesive layer for a dicing or a die bonding sheet, which have both a wafer-fixing function and a die adhesive function, including an acrylic polymer, a reactive double bond group containing epoxy resin and the heat curable agent, and when required, fillers such as silica (the patent document 2). Reliability of the semiconductor device manufactured by using the adhesive sheet of the patent document 2 can be enhanced significantly.

### PRIOR ART DOCUMENT

Patent document 1: JP Patent Application Laid Open No. 2011-228450
Patent document 2: JP Patent Application Laid Open No. 2008-133330

### DISCLOSURE OF THE INVENTION

### Means for Solving the Problems

Considering a sheet (a composite sheet for resin film formation) for forming a resin film having the above-mentioned functions including chip backside protective function or wafer-fixing function and die adhesive function, the present inventors have carried out keen examination to combine the technology of patent document 1 with that of patent document 2; and the following problems have occurred.

Namely, an adhesive between the pressure-sensitive adhesive layer of the dicing tape and the film for resin film formation may become excessive during pickup of the semiconductor chip together with the film for resin film formation from the dicing tape (the pressure-sensitive adhesive sheet). Thus defects, such as being unable to pickup or breaking the chips during the pickup, may be found.

The object of the present invention is to provide the composite sheet for resin film formation having a configuration in which the film for resin film formation is formed atop the pressure-sensitive adhesive sheet, wherein the reliability of an element (e.g. the semiconductor chip) on which the resin film is formed using the film for resin film formation is improved, and the aptitude for the pickup of the element having the film for resin film formation from the pressure-sensitive adhesive sheet is improved.

### Means for Solving the Object

The invention solving the above problems includes the gist below.

[1] A composite sheet for resin film formation composing a pressure-sensitive adhesive sheet having a pressure-sensitive adhesive layer on a base and a heat curable film for resin film formation provided on the pressure-sensitive adhesive layer, wherein

the film for resin film formation includes a binder component having a reactive double bond group, and

the pressure-sensitive adhesive layer is composed of a non-energy ray curable pressure-sensitive adhesive composition or a cured product of an energy ray curable pressure-sensitive adhesive composition.
[2] The composite sheet for resin film formation as described in the above [1], wherein the pressure-sensitive adhesive layer is composed of the non-energy ray curable pressure-sensitive adhesive composition, the non-energy ray curable pressure-sensitive adhesive composition includes a polymer having a reactive functional group and a crosslinking agent, and a crosslinkable functional group included in the crosslinking agent is 1 equivalent or more relative to the reactive functional group.
[3] The composite sheet for resin film formation as described in the above [2], wherein the non-energy ray curable pressure-sensitive adhesive composition further includes a plasticizer.
[4] The composite sheet for resin film formation as described in the above [2] or [3], wherein the polymer having the reactive functional group is an acrylic polymer having a glass transition temperature in a range of −45 to 0° C.
[5] The composite sheet for resin film formation as described in any one of the above [1] to [4], wherein the film for resin film formation further includes filler on which the surface thereof is modified by a compound having a reactive double bond group.
[6] The composite sheet for resin film formation as described in any one of the above [1] to [5], wherein the film for resin film formation is a die bonding adhesive film adhering a semiconductor chip to a die placement part.
[7] The composite sheet for resin film formation as set forth in any one of the above [1] to [5], wherein the film for resin film formation is a film for protective film formation which forms a film protecting backside of a face-down type semiconductor chip.

### The Effect of the Invention

According to the present invention, in regards with the composite sheet for resin film formation, the reliability of an element on which the resin film is formed using the film for resin film formation is improved, and the aptitude for the pickup of the element having the film for resin film formation from the pressure-sensitive adhesive sheet is superior.

### BRIEF DESCRIPTION OF THE DRAWINGS

FIG. 1 shows the attachment state of the composite sheet for resin film formation according to the first embodiment to the jig.

FIG. 2 shows the attachment state of the composite sheet for resin film formation according to the second embodiment to the jig.

FIG. 3 shows the attachment state of the composite sheet for resin film formation according to the third embodiment to the jig.

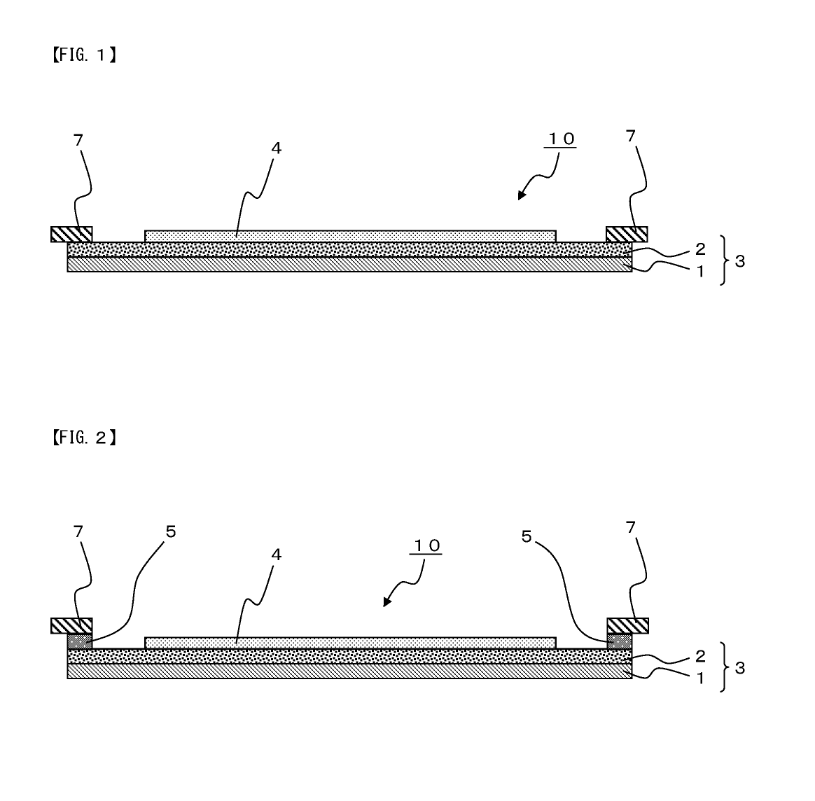

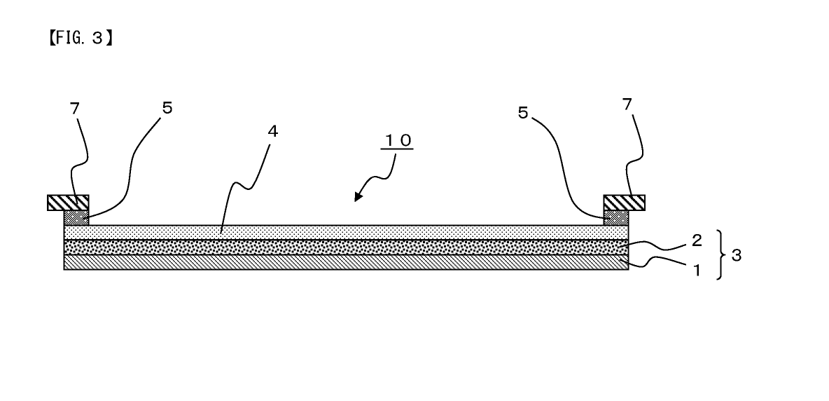

Hereinafter, further detail of the composite sheet for resin film formation of the present invention will be described. As shown in FIGS. 1 to 3, composite sheet for resin film formation 10 of the invention includes pressure-sensitive adhesive sheet 3 having pressure-sensitive adhesive layer 2 on base 1 and film for resin film formation 4 having a heat curable property provided on pressure-sensitive adhesive layer 2. Further, as shown in FIGS. 1 to 3, composite sheet for resin film formation 10 may be attached to jig 7, a ring frame and the like, when in use. As shown in FIGS. 2 and 3, a ring shaped jig adhesive layer 5 may be set at the outer peripheral part of the composite sheet for resin film formation 10 to improve adhesiveness with jig 7.

### (The Pressure-Sensitive Adhesive Sheet)

Pressure-sensitive adhesive sheet 3 has pressure-sensitive adhesive layer 2 on base 1. Major function of the pressure-sensitive adhesive sheet is to hold the chip, which a work such as a semiconductor wafer or so is separated through dicing. And in some cases, as shown in FIG. 1, the pressure-sensitive adhesive sheet is attached to jig 7 by the outer peripheral part of the pressure-sensitive adhesive layer and fixes the work, the chip and the composite sheet for resin film formation itself.

### (The Base)

The base is not particularly limited, and for example polyethylene film, polypropylene, film, polybutene film, polybutadiene film, polymethylpentene film, polyvinyl chloride film, vinyl chloride copolymer film, polyethylene terephthalate film, polyethylene naphthalate film, polybutyleneterephthalate film, polyurethane film, ethylene vinyl acetate copolymer film, ionomer resin film, ethylene(meth)acrylic acid copolymer film, ethylene(meth)acrylate copolymer film, polystyrene film, polycarbonate film, polyimide film, fluorine resin film or so is used. Also, the crosslinked film thereof may be used as well. Further, it may be a laminated film thereof

Thickness of the base is not particularly limited, and it is preferably 20 to 300 μm, and more preferably 60 to 100 μm. The composite sheet for resin film formation shows sufficient flexibility when said base thickness is within the above-range, thus shows good attachment ability to the work, such as semiconductor wafer and the like.

In addition, in order to improve wettability of the pressure-sensitive adhesive composition forming the pressure-sensitive adhesive layer, a face where the base contacts the pressure-sensitive adhesive layer may be corona treated or the other layer such as primer may be set.

### (The Pressure-Sensitive Adhesive Layer)

The pressure-sensitive adhesive layer is composed of the non-energy ray curable pressure-sensitive adhesive composition or a cured product of the energy ray curable pressure-sensitive adhesive composition. The above pressure-sensitive adhesive layer is superior in the aptitude for the pickup of the chips with the film for resin film formation or the chips with the resin film formation mentioned below. Note the pressure-sensitive adhesive layer of the invention is preferably the pressure-sensitive adhesive layer composed of the non-energy ray curable pressure-sensitive adhesive composition considering the following points. Said pressure-sensitive adhesive layer does not require an energy ray irradiation step, such as an ultra violet ray irradiation step, in the manufacturing step of the composite sheet for resin film formation, and that the manufacturing step can be simplified. And in case when the energy ray is irradiated to the film for resin film formation in order to improve a cohesive strength of the film for resin film formation after the film for resin film formation of the composite sheet for resin film formation is attached to the adherend, the pickup will not be difficult. The cured product of energy ray curable pressure-sensitive adhesive composition or the non-energy ray curable pressure-sensitive adhesive composition does not substantially include unreacted reactive double bond group, or included to an extent of giving no influence to effects of the invention. In concrete, change rate of the pressure-sensitive adhesive force before and after the energy ray irradiation of the pressure-sensitive adhesive sheet having the pressure-sensitive adhesive layer composed of the cured product of energy ray curable pressure-sensitive adhesive composition or the non-energy ray curable pressure-sensitive adhesive composition is within a range of 90 to 100%. The change rate of the pressure-sensitive adhesive force can be measured by the following method. First, the pressure-sensitive adhesive sheet is cut to a length of 200 mm and a width of 25 mm, and a pressure-sensitive adhesive force measurement sheet is prepared. Next, the pressure-sensitive adhesive layer of the pressure-sensitive adhesive force measurement sheet is attached to a mirror face of the semiconductor wafer, and a multilayered body composed of the semiconductor wafer and the pressure-sensitive adhesive force measurement sheet is obtained. The obtained multilayered body is left in an atmosphere of 23° C., 50% relative humidity for 20 minutes. 180° peeling test (a part on the side where the pressure-sensitive adhesive force measurement sheet is peeled) is performed to the left multilayered body conforming JIS Z0237:2000, and the pressure-sensitive adhesive force (unit is mN/25 mm) before the energy ray irradiation is measured. In addition, the energy ray irradiation (220 mW/cm², 160 mJ/cm²) is performed to the left multilayered body, and the pressure-sensitive adhesive force (unit is mN/25 mm) after the energy ray irradiation is measured in the same method as above. And, change rate is calculated from the measured pressure-sensitive adhesive forces before and after the energy ray irradiation.

The reactive double bond group of the invention is a functional group including a polymerizable carbon-carbon double bond; concrete examples thereof are a vinyl group, an allyl group, a (meth)acryloyl group, a (meth)acryloxy group, and etc., and a preferable example is an acryloyl group. The reactive double bond group of the invention easily produces polyaddition reactions by generating radicals in the presence of radicals, and thus, it does not include double bonds which do not have polymerizability. For instance, each component constituting the non-energy ray curable pressure-sensitive adhesive composition may include aromatic rings; however, unsaturated structure of the aromatic ring is not the reactive double bond group of the invention.

<The Pressure-Sensitive Adhesive Layer Composed of the Non-Energy Ray Curable Pressure-Sensitive Adhesive Composition>

The non-energy ray curable pressure-sensitive adhesive composition is not particularly limited, and at least includes polymer component (A) (Hereinafter, it may be referred to as “component (A)”. The same applies to the other components.) In the invention, it is preferable to include polymer including reactive functional groups as component (A), crosslinking agent (B), and further a plasticizer (C), in order to provide sufficient pressure-sensitive adhesive property and a film formation property (a sheet formation property) to the non-energy ray curable pressure-sensitive adhesive composition.

The reactive functional group of the invention is the functional group reactive with a crosslinkable functional group included in the latter-mentioned crosslinking agent (B) or crosslinking agent (K). Concrete examples thereof are a carboxyl group, an amino group, an epoxy group, a hydroxyl group, and etc.

Hereinafter, an acrylic pressure-sensitive adhesive composition including acrylic polymer (A1) as an example of polymer component (A) will be described in detail.

### (A1) Acrylic Polymer

Acrylic polymer (A1) is a polymer including (meth)acrylate monomer or derivatives thereof at least in a monomer constituting acrylic polymer (A1) and preferably including the reactive functional group. The reactive functional group of acrylic polymer (A1) forms a three dimensional network structure by reacting with the crosslinkable functional group of crosslinking agent (B), and the cohesive strength of the pressure-sensitive adhesive layer is heightened. As a result, the resin film for resin film formation provided on the pressure-sensitive adhesive layer or the resin film obtained by curing said resin film for resin film formation (Hereinafter, merely referred to as “resin film”) can be easily released from the pressure-sensitive adhesive layer.

As the reactive functional group of acrylic polymer (A1), a hydroxyl group is preferable since it is selectively reactive with an organic polyvalent isocyanate compounds preferably used as crosslinking agent (B). The reactive functional group can be introduced to acrylic polymer (A1) by using monomer having the reactive functional group, such as below-mentioned (meth)acrylate having hydroxy group, (meth)acrylate having carboxyl group, (meth)acrylate having amino group, (meth)acrylate having epoxy group, monomer having carboxyl group other than (meth)acrylate such as (meth)acrylic acid or itaconic acid, monomer having hydroxy group other than (meth)acrylate such as vinyl alcohol or N-methylol methacrylamide, etc.

In this case, acrylic polymer (A1) is preferable to include 1 to 50 mass % and more preferable to include 2 to 15 mass % of monomer having the reactive functional group with respect to the whole monomer constituting said acrylic polymer (A1). In case when a content of the monomer having the reactive functional group in acrylic polymer (A1) exceeds 50 mass %, mutual interaction force among the reactive functional groups generally having high polarity becomes excessive, which may create concerns that acrylic polymer (A1) becomes difficult to handle.

Weight average molecular weight of acrylic polymer (A1) is preferably ten thousand to two million, and more preferably ten thousand to a million and a half.

In the invention, weight-average molecular weight (Mw), number-average molecular weight (Mn) and molecular weight distribution (Mw/Mn) are measured by gel permeation chromatography method (GPC) method (polystyrene standard). Such methods are measured by using a high speed GPC device “HLC-8120GPC”, made by Tosoh Corp., or so connecting high speed columns of “TSK gurd column H_{XL}-H”, “TSK GEL GMH_{XL}” and “TSK gel G2000 H_{XL}” (all are made by Tosoh Corp.) in this order, with column temperature of 40° C., a liquid sending speed of 1.0 mL/min. and a differential refractometer as the detector.

Glass transition temperature (Tg) of acrylic polymer (A1) is within the range of preferably −60 to 0° C., more preferably −45 to 0° C. and the most preferably −35 to −15° C. By setting the glass transition temperature (Tg) of acrylic polymer (A1) within the above range, the aptitude for the pickup of the chips with film for resin film formation or the chips with resin film can be improved. In addition, the glass transition temperature (Tg) of acrylic polymer (A1) is within a range of −35 to −15° C., the aptitude for the pickup may be superior even when a plasticizer (C) is not compounded in the non-energy ray curable pressure-sensitive adhesive composition or the compound amount is small.

The glass transition temperature (Tg) of acrylic polymer (A1) can be adjusted according to combination of monomers constituting the acrylic polymer (A1). For instance, in order to raise the glass transition temperature, in case when using the latter mentioned alkyl(meth)acrylate in which a carbon number of alkyl group is 1 to 18 as the monomer constituting acrylic polymer (A1), methods such as selecting the alkyl(meth)acrylate in which the carbon number of alkyl group is small or increasing a content ratio of the alkyl(meth)acrylate in which the carbon number of alkyl group is small are mentioned.

Note, glass transition temperature (Tg) of acrylic polymer (A1) can be obtained by the following formula (FOX formula) based on the glass transition temperature of a homopolymer of monomer constituting acrylic polymer (A1). FOX formula is expressed by the following formula (1) wherein Tg of acrylic polymer (A1) is Tg copolymer, Tg of homopolymer of monomer X constituting acrylic polymer (A1) is Tgx, Tg of homopolymer of monomer Y constituting acrylic polymer (A1) is Tgy, molar fraction of monomer X is Wx (mol %) and molar fraction of monomer Y is Wy (mol %).

100/Tg copolymer=Wx/Tgx+Wy/Tgy (1)

In addition, FOX formula hold for additivity as shown in the above formula (1) even when acrylic polymer (A1) becomes copolymerized composition of 3 or more monomers.

As (meth)acrylate ester monomer and derivatives thereof, specifically alkyl(meth)acrylate in which carbon number of alkyl group is 1 to 18, (meth)acrylate having cyclic skeleton, (meth)acrylate having hydroxyl groups, (meth)acrylate having epoxy groups, (meth)acrylate having amino groups, (meth)acrylate having carboxyl groups are mentioned.

As alkyl(meth)acrylate in which the carbon number of alkyl group is 1 to 18, for instance, methyl(meth)acrylate, ethyl(meth)acrylate, propyl(meth)acrylate, butyl(meth)acrylate, pentyl(meth)acrylate, hexyl(meth)acrylate, heptyl(meth)acrylate, octyl(meth)acrylate, 2-ethylhexyl(meth)acrylate, nonyl(meth)acrylate, decyl(meth)acrylate, lauryl(meth)acrylate, tetradecyl(meth)acrylate, octadecyl(meth)acrylate and the like are mentioned.

As (meth)acrylate having cyclic skeleton, for instance, cycloalkyl(meth)acrylate, benzyl(meth)acrylate, isobornyl(meth)acrylate, dicyclopentanyl(meth)acrylate, dicyclopentenyl(meth)acrylate, dicyclopentenyloxyethyl(meth)acrylate, imide(meth)acrylate or so may be mentioned.

As (meth)acrylate having the hydroxyl group, for instance, 2-hydroxyethyl(meth)acrylate, 2-hydroxypropyl(meth)acrylate, 2-hydroxybutyl(meth)acrylate or so may be mentioned.

As (meth)acrylate having the epoxy group, glycidyl(meth)acrylate or so may be mentioned.

As (meth)acrylate having the amino group, for instance, monoethylamino (meth)acrylate, diethylamino (meth)acrylate or so may be mentioned.

As (meth)acrylate having the carboxyl group, for instance, 2-(meth)acryloyloxyethylphthalate, 2-(meth)acryloyloxypropylphthalate or so may be mentioned.

In addition, acrylic polymer (A1) may be copolymerized with monomer having the carboxyl groups other than (meth)acrylate such as (meth)acrylic acid, itaconic acid or so, monomer having hydroxyl group other than (meth)acrylate such as vinyl alcohol, N-methylol methacrylamide or so and (meth)acrylonitrile, (meth) acrylamide, vinyl acetate, styrene or so. These can be used alone or by combining two or more thereof. Acrylic polymer (A1) can be manufactured using the above monomers, in accordance with the conventional method such as emulsion polymerization method.

(B) Crosslinking Agent

In the invention, crosslinking agent (B) is preferably added to the non-energy ray curable pressure-sensitive adhesive composition in order to provide cohesiveness to the pressure-sensitive adhesive layer. As the crosslinking agent, an organic polyvalent isocyanate compound, an organic polyvalent epoxy compound, an organic polyvalent imine compound, a metal chelate-based crosslinking agent or so may be mentioned. Among all, the organic polyvalent isocyanate compound is preferable for high reactivity.

As the organic polyvalent isocyanate compounds, aromatic polyvalent isocyanate compounds, aliphatic polyvalent isocyanate compounds, alicyclic polyvalent isocyanate compounds and trimer of the organic polyvalent isocyanate compounds thereof, isocyanurate products, adduct products (ethylene glycol, propylene glycol, neopentyl glycol, trimethylolpropane, reactants with low molecular active hydrogen-containing compound, such as castor oil: e.g. trimethylolpropane adduct xylenediisocyanate or so), isocyanate-terminal urethane prepolymer obtained by reaction between organic polyvalent isocyanate compounds and polyol compounds and so on can be mentioned.

As for specific example of the organic polyvalent isocyanate compound, 2,4-tolylenediisocyanate, 2,6-tolylenediisocyanate, 1,3-xylylenediisocyanate, 1,4-xylenediisocyanate, diphenylmethane-4,4′-diisocyanate, diphenylmethane-2,4′-diisocyanate, 3-methyldiphenylmethanediisocyanate, hexamethylenediisocyanate, isophoronediisocyanate, dicyclohexylmethane-4,4′-diisocyanate, dicyclohexylmethane-2-4′-diisocyanate, trimethylolpropaneadduct tolylenediisocyanate, lysine isocyanate or so may be mentioned.

As for the specific examples of the organic polyvalent epoxy compound, 1,3-bis(N,N′-diglycidylaminomethyl)cyclohexane,N,N,N′,N′-tetraglycidyl-m-xylylendiamine, ethyleneglycoldiglycidyl ether, 1,6-hexanedioldiglycidyl ether, trimethylolpropanediglycidyl ether, diglycidylaniline, diglycidyl amine and so may be mentioned.

As for the specific examples of organic polyvalent imine compounds, N—N′-diphenylmethane-4,4′-bis(1-aziridinecarboxyamide), trimethylolpropane-tri-β-aziridinylpropionate, tetramethylolmethane-tri-β-aziridinylpropionate, and N,N′-toluene-2,4-bis(1-aziridinecarboxyamide)triethylenemelamine or so may be mentioned.

As for the specific examples of the metal chelate-based crosslinking agent, zirconium chelate-based crosslinking agents such as tri-n-butoxyethyl acetoacetate zirconium, di-n-butoxybis(ethyl acetoacetate)zirconium, n-butoxytris(ethyl acetoacetate)zirconium, tetrakis(n-propyl acetoacetate)zirconium, tetrakis(acetyl acetoacetate)zirconium, tetrakis(ethyl acetoacetate)zirconium; titanium chelate-basedcrosslinking agents such as diisopropoxy.bis(ethyl acetoacetate) titanium, diisopropoxy.bis(acetylacetate) titanium, diisopropoxy.bis(acetylacetone) titanium; and aluminumchelate-basedcrosslinking agents such as diisopropoxyethyl acetoacetate aluminum, diisopropoxyacetyl acetonatealuminum, isopropoxy bis(ethyl acetoacetate)aluminum, isopropoxybis(acetylacetonate)aluminum, tris(ethyl acetoacetate)aluminum, tris(acetylacetonate)aluminum, mono acetylacetonate bis(ethyl acetoacetate)aluminum or so may be mentioned.

These may be used alone, or by combining two or more thereof.

The crosslinkable functional groups, such as isocyanate groups, of crosslinking agent (B) as mentioned above, react with the reactive functional groups, such as hydroxyl group, of acrylic polymer (A1). The crosslinkable functional group is preferably the equivalent of 1 or more, more preferably the equivalent of 1 to 5 with respect to the reactive functional group. Determination of the crosslinkable functional group number in the crosslinking agent with respect to the reactive functional group number in acrylic polymer (A1) of the composite sheet for resin film formation according to the invention within the above range suppresses the deterioration of the cohesiveness of the pressure-sensitive adhesive layer. In addition, in case when the non-energy ray curable pressure-sensitive adhesive composition includes the latter mentioned plasticizer (C), plasticizer (C) ooze out to the film formation for resin film or to the interface between the resin film and the pressure-sensitive adhesive layer, while uniformly holding plasticizer (C) in the three dimensional network structure formed in the pressure-sensitive adhesive layer; thus, excessive deterioration of the adhesiveness can be suppressed. Consequently, the composite sheet for resin film formation superior in the aptitude for dicing and for pickup can be obtained.

Crosslinking agent (B) is preferably 5 to 60 parts by mass, more preferably 10 to 50 parts by mass, and the most preferably 15 to 50 parts by mass with respect to 100 parts by mass of acrylic polymer (A1). Adjustment of the crosslinkable functional group number in the crosslinking agent with respect to the reactive functional group number in acrylicpolymer becomes easy when the compound amount of the crosslinking agent is within the above range.

### (C) Plasticizer

As for the specific examples of plasticizer (C), 1,2-cyclohexyldicarboxylic acid esters, phthalic acid esters, adipic acid esters, trimellitic esters, pyromellitic acid esters, benzoic acid esters, phosphoric esters, citric acid esters, sebacic acid esters, azelaic acid esters, maleic acid esters or so may be mentioned. With the use of such plasticizer (C), the aptitude for the dicing of 40 to 150 μm thick thin wafer or the aptitude for the pickup of chips with the film for resin film formation or chips with the resin film become good.

Among all, organic acid ester compounds, in which a part of or the whole of polycarboxylic acid wherein two or more carboxyl groups are added to the aromatic ring or the cycloalkyl ring are esterified with alcohol, are preferable for improving the aptitude for the pickup. Among all, 1,2-cyclohexyldicarboxylic acid ester, phthalic acid ester, pyromellitic acid esters and trimellitic ester are more preferable; In concrete, organic acid ester compounds shown by the following formulas (I) to (IV), in which a part of or the whole of carboxylic groups in polycarboxylic acid are esterified with alcohol. As for the specific examples of alcohol esterified with carboxyl groups of polycarboxylic acid, ethanol, 2-ethylhexanol, cyclohexanol, 1-hexanol, 1-pentanol, 1-nonanol, isononanol, 1-butanol, 2-benzyl-1-butanol, isodecanol, 1-octanol or so may be mentioned. Esters of two or more kinds thereof can be present in a molecule.

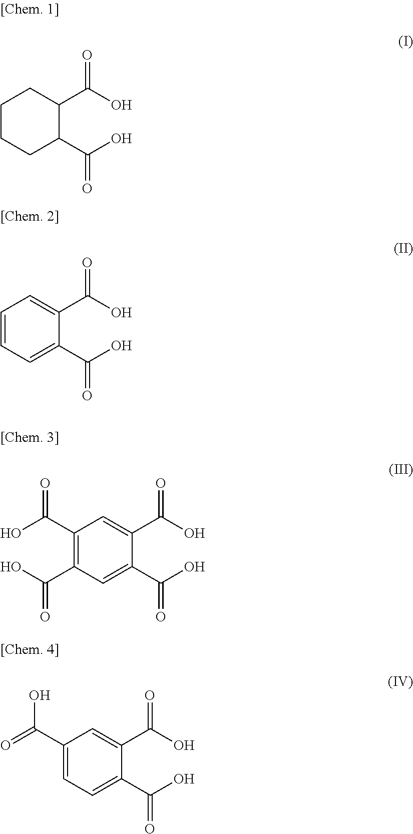 [SMILES: O=C(O)C1CCCCC1C(=O)O ; O=C(O)c1ccccc1C(=O)O ; O=C(O)c1cc(C(=O)O)c(C(=O)O)cc1C(=O)O ; O=C(O)c1ccc(C(=O)O)c(C(=O)O)c1]

Content of plasticizer (C) with respect to 100 parts by mass of acrylic polymer (A1) is preferably 5 to 70 parts by mass, more preferably 10 to 60 parts by mass and the most preferably 20 to 50 parts by mass. In case when content of plasticizer (C) is within the above range, the aptitude for the dicing of thin wafer and the aptitude for the pickup of chips with the film for resin film formation or chips with the resin film can further be improved.

In addition, as for the other component of the non-energy ray curable pressure-sensitive adhesive composition, die, pigment, degradation inhibitor, antistatic agent, flame retardant, silicone compound, chain transfer agent or so may be added.

<The Pressure-Sensitive Adhesive Layer Composed of Cured Products of the Energy Ray Curable Pressure-Sensitive Adhesive Composition>

The energy ray curable pressure-sensitive adhesive composition at least includes polymer (A) and energy ray curable compound (D) or energy ray curable polymer (AD) having properties of both component (A) and component (D). Further, polymer component (A), energy ray curable compound (D) and energy ray curable polymer (AD) can be used simultaneously.

The above-mentioned examples of the above non-energy ray curable pressure-sensitive adhesive composition can be used as polymer component (A).

Energy ray curable compound (D) includes the reactive double bond groups, therefore, polymer cured when irradiated by energy rays such as ultraviolet rays, electron beam or so, and has function to lower pressure-sensitive adhesiveness of the pressure-sensitive adhesive composition. Energy ray curable polymer (AD) has properties for both polymer function and energy ray curable property.

In addition, the energy ray curable pressure-sensitive adhesive composition may include other component in order to improve physical properties when necessary. As for the other component, photopolymerization initiator (E) other than the above-mentioned examples of the non-energy ray curable pressure-sensitive adhesive composition can be exemplified.

Hereinafter, similar with the above-described non-energy ray curable pressure-sensitive adhesive composition, acrylic pressure-sensitive adhesive composition including acrylic polymer (A1) as polymer component (A) will be described in detail as an example.

### (D) Energy Ray Curable Compound

Energy ray curable compound (D) is a compound which is polymer cured when irradiated by energy rays, such as ultraviolet rays, electron beam or so. As for the specific examples of the energy ray curable compound, low molecular weight compounds (monofunctional or polyfunctional of monomers or oligomers) having the reactive double bond groups are exemplified. In concrete, acrylates such as trimethylolpropane triacrylate, tetramethylolmethane tetraacrylate, pentaerythritol triacrylate, dipentaerythritol monohydroxy pentaacrylate, dipentaerythritol hexaacrylate, 1,4-butylene glycol diacrylate, 1,6-hexanediol diacrylate, acrylates having a ring shaped aliphatic skeleton such as dicyclopenta diene dimethoxy diacrylate and iso-bornyl acrylate, acrylate compounds such as polyethylene glycoldiacrylate, oligoester acrylate, urethan acrylate oligomer, epoxy-modified acrylate, polyether acrylate or so are mentioned. Such compounds generally have a molecular weight of 100 to 30,000, preferably 300 to 10,000 or so.

In general, the low molecular weight compound having the reactive double bond group is used in an amount of about preferably 0 to 200 parts by mass, more preferably 1 to 100 parts by mass, and further preferably 1 to 30 parts by mass, with respect to 100 parts by mass of component (A), including energy ray curable polymer (AD) mentioned below.

### (AD) Energy Ray Curable Polymer

The reactive double bond group is bonded to main chain, side chain or ends of polymer of energy ray curable polymer (AD), having properties of above-mentioned components (A) and (D).

Examples of the reactive double bond group bonded to main chain, side chain or ends of energy ray curable polymer are as mentioned above. The reactive double bond group may be bonded to main chain, side chain or ends of energy ray curable polymer via an alkylene group, an alkylene oxy group, a polyalkylene oxy group.

Weight average molecular weight (Mw) of the reactive double bond group bonded energy ray curable polymer (AD) is preferably ten thousand to two million, and more preferably ten thousand to a million and a half. Further, glass transition temperature (Tg) of energy ray curable polymer (AD) is within a range of preferably −45 to 0° C. and more preferably −35 to −15° C. Note, in case of energy ray curable polymer (AD) which is obtained by reacting acrylic polymer (A1), having the reactive functional group such as hydroxyl group, and compounds having polymerizable groups mentioned below, Tg is Tg of acrylic polymer (A1) before reacting with the compounds having polymerizable groups.

Energy ray curable polymer (AD) is obtained by reacting acrylic polymer (A1), having the reactive functional groups such as carboxyl groups, amino groups, epoxy groups, hydroxy groups or so, and polymerizable group containing compound, having substituents reactive with said reactive functional groups and 1 to 5 reactive double bond groups in a molecule. Acrylic polymer (A1) is preferably a polymer composed of (meth)acrylate monomer having the reactive functional groups or derivatives thereof. As for the polymerizable group containing compound, (meth)acryloyloxyethyl isocyanate, meta-isopropenyl α,α-dimethyl benzylisocyanate, (meth)acryloyl isocyanate, allylisocyanate, glycidyl(meta)acrylate, (meth)acrylic acid or so may be mentioned.

Energy ray curable polymer (AD) may be crosslinked, in case when energy ray curable polymer (AD) is obtained by reacting acrylic polymer (A1) including the reactive functional groups and the polymerizable group containing compound. In case when crosslinking agent is added, the energy ray curable polymer (AD) is crosslinked by the reaction of the crosslinkable functional group in the crosslinking agent and the reactive functional group, and the cohesive strength of the pressure-sensitive adhesive layer can be adjusted.

As the crosslinking agent, examples mentioned in the above non-energy ray curable pressure-sensitive adhesive composition may be used. The crosslinking agent is used in a ratio of preferably 0.01 to 20 parts by mass, more preferably 0.1 to 15 parts by mass, and the most preferably 0.5 to 12 parts by mass, with respect to 100 parts by mass of acrylic polymer (A1).

The acrylic pressure-sensitive adhesive composition including acrylic polymer (A1) and energy ray curable compound (D) and the acrylic pressure-sensitive adhesive composition including energy ray curable polymer (AD) as mentioned above are cured by energy ray irradiation. In concrete, ultraviolet rays, electron beam or so may be used as the energy ray.

### (E) Photopolymerization Initiator

Combination of photopolymerization initiator (E) with energy ray curable compound (D) or energy ray curable polymer (AD) shortens curing time of the polymer and amount of beam irradiation can be reduced.

As such photopolymerization initiator, benzophenone, acetophenone, benzoin, benzoinmethylether, benzoinethylether, benzoin isopropyl ether, benzoin isobutyl ether, benzoin benzoic acid, benzoin benzoic acid methyl, benzoin dimethyl ketal, 2,4-diethyl thioxanthen, 1-hydroxycyclohexyl phenyl ketone, benzyldiphenyl sulfide, tetramethyl thiuram monosulfide, azobisisobutyronitrile, benzyl, dibenzyl, diacetyl, 1,2-diphenylmethane, 2-hydroxy-2-methyl-1-[4-(1-methyl vinyl)phenyl]propanone, 2,4,6-trimethylbenzoyldiphenylphosphine oxide and β-chloro anthraquinone or so may be mentioned. These may be used alone, or by combining two or more kinds of the photopolymerization initiator may be used.

Blending ratio of the photopolymerization initiator is preferably 0.1 to 10 parts by mass and more preferably 1 to 5 parts by mass with respect to 100 parts by mass of energy ray curable compound (D) or energy ray curable polymer (AD).

Sufficient curable property may not be obtained for insufficient photopolymerization in case when blending ratio of the photopolymerization initiator is less than 0.1 parts by mass, while residues which do not contribute to photopolymerization may generate causing faults when blending ratio of the photopolymerization initiator exceeds 10 parts by mass.

The energy ray curable pressure-sensitive adhesive composition is preferable to include the above components, and the pressure-sensitive adhesive layer is composed of cured product of such energy ray curable pressure-sensitive adhesive composition. The pressure-sensitive adhesive layer composed of the cured product of energy ray curable pressure-sensitive adhesive composition is obtained by curing a coating film of the acrylic pressure-sensitive adhesive composition including acrylic polymer (A1) and energy ray curable compound (D) and acrylic pressure-sensitive adhesive composition including energy ray curable polymer (AD) by energy ray irradiation described in a manufacturing method of the composite sheet for resin film formation mentioned below.

Thickness of the pressure-sensitive adhesive layer is not particularly limited and is generally 1 to 100 μm, preferably 1 to 60 μm and more preferably 1 to 30 μm.

### (The Film for Resin Film Formation)

The functions at least required to the film for the resin film formation are the sheet form maintaining property (1), the initial adhesiveness (2) and the curability (3).

Addition of binder component having the reactive double bond group allows providing sheet form maintaining property (1) and curability (3) to the film for resin film formation. In addition, the binder component includes the below mentioned epoxy group other than the reactive double bond group, thus, curing of the film for resin film formation is realized by forming three dimensional network structure by addition polymerization between epoxy groups and between the reactive double bond groups. As a result, the film for resin film formation can improve reliability of semiconductor device more than the film for resin film formation composed of binders not having the reactive double bond group. In addition, in case when adding filler (H), having the below mentioned reactive double bond groups on surface, to the film for resin film formation, the binder component having the reactive double bond groups has high compatibility with said filler (H) compared to the binder not having the reactive double bond groups.

As the binder component having the reactive double bond groups, polymer component (F) and heat curable component property (G) can be mentioned. The reactive double bond group can be included at least in either the polymer component (F) or heat curable component (G). Note that, the initial adhesiveness (2) which is the property to temporarily adhere the film for resin film formation to the work until the curing may be a pressure sensitive property or it may be a property to adhere by softening by heat. The initial adhesiveness (2) is usually controlled by various characteristics of the binder component or by the blending amount of the filler (H) which will be described in below.

### (F) the Polymer Component

Polymer component (F) is added mainly for the purpose to provide sheet form maintaining property to the film for resin film formation.

In order to achieve said purpose, it is preferable that weight-average molecular weight (Mw) of the polymer component (F) is generally 20,000 or more, and more preferably 20,000 to 3,000,000.

As polymer component (F), an acrylic polymer, polyester, phenoxy resin, polycarbonate, polyether, polyurethane, polysiloxane, rubber polymer and the like can be used. Further, two or more kinds thereof, such as acrylic urethane resin or so obtainable by reaction between an acrylic polyol, which is an acrylic polymer having a hydroxy group, and urethane prepolymer having isocyanate group at molecular ends may also be used. Further, those combining two or more may be used as well including the polymer binding two or more thereof.

### (F1) Acrylic Polymer

Acrylic polymer (F1) is preferably used for polymer component (F). Glass transition temperature (Tg) of acrylic polymer (F1) is within a range of preferably −60 to 50° C., more preferably −50 to 40° C., and the most preferably −40 to 30° C. When the glass transition temperature of acrylic polymer (F1) is high, adhesiveness of the film for resin film formation declines and it may not be able to transfer to the work.

The weight average molecular weight (Mw) of acrylic polymer (F1) is preferably 100,000 to 1,500,000. If the weight average molecular weight of acrylic polymer (F1) is high, the adhesiveness of the film for resin film formation declines and it may not be able to transfer to the work.

Acrylic polymer (F1) includes (meth)acrylate monomer or derivatives thereof at least in the monomer constituting thereof. As (meth)acrylate monomer or derivatives thereof, the above-mentioned examples of acrylic polymer (A1) can be mentioned. Note, the monomer including the carboxyl group may be used as the monomer constituting acrylic polymer (F1), however, in case of using the epoxy based heat curable component as the below-mentioned heat curable component (G), it is preferable that the used amount of the monomer having the carboxyl group is small since said carboxyl group and the epoxy group in the epoxy based heat curable component react.

In case when acrylic polymer (F1) has the reactive double bond group, said reactive double bond group is added in a unit of or to ends of a continuous structure which is the skeleton of acrylic polymer (F1).

Acrylic polymer (F1) having the reactive double bond group is obtained by reacting the acrylic polymer having the reactive functional groups and the polymerizable group containing compound having substituents reactive with said reactive functional groups and 1 to 5 reactive double bond groups in a molecule. As the reactive double bond group having acrylic polymer (F1), the vinyl group, the allyl group, the (meth)acryloyl group or so is preferably exemplified. The reactive functional group having acrylic polymer (F1) is synonymous with the reactive functional group in component (A), and the acrylic polymer having the reactive functional group is obtainable by the method described for the component (A). As polymerizable group containing compound, it is the same as examples shown in component (AD).

Acrylic polymer (F1) is preferable to include the reactive functional group when the film for resin film formation include below-mentioned crosslinking agent (K).

Among all, acrylic polymer (F1) having the hydroxy group as the reactive functional group is preferable since it is easy to manufacture, and is easy to introduce a crosslinking structure using crosslinking agent (K). Further, acrylic polymer (F1) having hydroxy group is superior in compatibility with heat curable component (G) mentioned below.

In case when introducing the reactive functional group to acrylic polymer (F1) using monomer having the reactive functional group as the monomer constituting acrylic polymer (F1), ratio of monomer having the reactive functional group with respect to a total mass of the monomer constituting acrylic polymer (F1) is preferably 1 to 20 mass % or so, and more preferably 3 to 15 mass %. In case when a constituent unit derived from monomer having the reactive functional group in acrylic polymer (F1) is within the above range, the reactive functional group and the crosslinkable functional group of crosslinking agent (K) react, and form the three dimensional network structure which heighten crosslinking density of acrylic polymer (F1). As a result, the film for resin film formation is superior in the shear strength. Further, a semiconductor device superior in package reliability can be obtained since absorbing property of the film for resin film formation decreases.

### (F2) Non-Acrylic Based Resin

In addition, as polymer component (F), one kind solely or a combination of two or more kinds of non-acrylic based resin (F2) selected from polyester, phenoxy resin, polycarbonate, polyether, polyurethane, polysiloxane, rubber polymer or a combination of two kinds or more thereof may be used. Weight-average molecular weight of said resin is preferably 20,000 to 100,000, and more preferably 20,000 to 80,000.

Glass transition temperature of non-acrylic based resin (F2) is within a range of preferably −30 to 150° C., and more preferably −20 to 120° C.

In case when non-acrylic based resin (F2) is used simultaneously with the abovementioned acrylic polymer (F1), interlayer release between the pressure-sensitive adhesive sheet and the film for resin film formation can be easily performed when transferring the film for resin film formation to the work, and the film for resin film formation follows the transfer surface, which further suppresses occurrence of voids.

In case when non-acrylic based resin (F2) is used simultaneously with the abovementioned acrylic polymer (F1), content of the non-acrylic based resin (F2) is, in mass ratio (F2:F1) of non-acrylic based resin (F2) and acrylic polymer (F1), it is generally 1:99 to 60:40, preferably 1:99 to 30:70. The above effects can be obtained when said content of non-acrylic based resin (F2) is within the above range.

In case when acrylic polymer (F1), having the epoxy group on the side chain, or phenoxy resin are used as polymer component (F), the epoxy group of the polymer component (F) may be involved in the heat curing, however, such polymers or resins of the invention is treated as polymer component (F) rather than heat curing component (G).

### (G) Heat Curable Component

Heat curable component (G) is added to the film for resin film formation mainly for the purpose to provide the heat curable property.

The heat curable component (G) preferably includes the compound having the epoxy group (hereinafter, merely referred to as “epoxy compound”), and uses a combination of the epoxy compound and the heat curable agent. Heat curable component (G) is used by combining with polymer component (F), hence from the point of suppressing the viscosity of the composition for coating which is to form the film for resin film formation, and to improve the handling property, the weight average molecular weight (Mw) thereof is usually 10,000 or less and preferably 100 to 10,000.

As the epoxy compound, there are epoxy compound (G1) having the reactive double bond group and epoxy compound (G1′) not having the reactive double bond group. As the heat curable agent, heat curable agent (G2) having the reactive double bond group and heat curable agent (G2′) not having the reactive double bond group. In case when heat curable component (G) has the reactive double bond group, either epoxy compound (G1) having the reactive double bond group or heat curable agent (G2) having the reactive double bond group is included as an essential component.

### (G1) Epoxy Compound Having the Reactive Double Bond Group

As epoxy compound (G1) having the reactive double bond group, it is preferable to include the aromatic ring since strength or heat resistant property of the film for resin film formation after heat curing improves. As the reactive double bond group of epoxy compound (G1), vinyl group, allyl group, (meth)acryloyl group or so are preferable, (meth)acryloyl group is more preferable, and acryloyl group is the most preferable.

As epoxy compound (G1) having the reactive double bond group, a compound in which a part of the epoxy group of the polyfunctional epoxy compound is converted to a group including the reactive double bond group can be mentioned. Such compound can be synthesized by such as performing addition reaction of an acrylic acid to the epoxy group. Other compound, in which the group including the reactive double bond group is directly bonded to the aromatic ring or so constituting the epoxy resin, can also be mentioned.

Here, as epoxy compound (G1) having the reactive double bond group, compounds shown by the following formula (1), compounds shown by the following formula (2) or compounds obtained by addition reaction of the acrylic acid to the epoxy group, a part of epoxy compound (G1′) not having the reactive double bond group, may be mentioned.

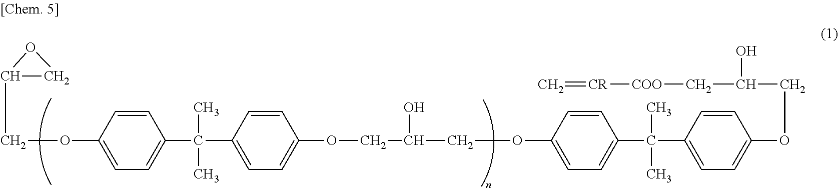

[“R” is H— or CH₃—, “n” is an integral number of 0 to 10]

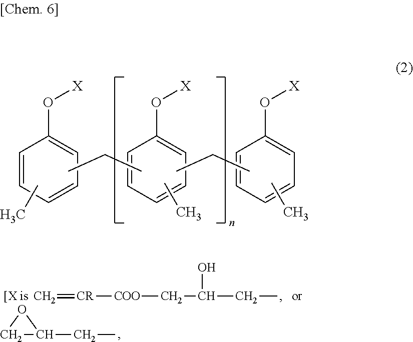

[“R” is H— or CH₃—, “n” is an integral number of 0 to 10]

Epoxy compound (G1) having the reactive double bond group obtained by a reaction between epoxy compound (G1′) not having the reactive double bond group and the acrylic acid may be a mixture of unreacted materials or compounds in which the epoxy groups are entirely consumed, however, epoxy compound (G1) of the invention can be any as long as it substantially contains the above compounds.

(G1′) Epoxy Compound not Having the Reactive Double Bond Group

As epoxy compound not having the reactive double bond group (G1′), the conventionally known epoxy compound can be used. Such epoxy compounds may exemplify epoxy compounds having two or more functional groups in a molecule; concrete examples thereof are polyfunctional based epoxy resin, biphenyl compound, bisphenol A diglycidyl ether, hydrogenated products thereof, cresol novolak type epoxy resin, dicyclopentadiene type epoxy resin, biphenyl type epoxy resin, bisphenol A type epoxy resin, bisphenol F type epoxy resin, phenylene skeleton type epoxy resin, phenol novolac type epoxy resin or so. These may be used alone, or by combining two or more thereof.

Number-average molecular weight of epoxy compounds (G1) and (G1′) are not particularly limited, however, considering curable property of the film for resin film formation or strength or heat resistant property after curing, it is preferably 300 to 30,000, more preferably 400 to 10,000, and the most preferably 500 to 10,000. In addition, content of the reactive double bond group in a total amount [(G1)+(G1′)] of said epoxy compound is 0.1 to 1,000 moles, preferably 1 to 500 moles, and the most preferably 10 to 400 moles with respect to 100 moles of the epoxy group in the total amount of said epoxy compound. In case when content of the reactive double bond group in the total amount of the epoxy compound exceeds 1,000 moles, it is likely that the heat curable property may be insufficient.

The heat curable agent functions as the curing agent of the epoxy compounds (G1) and (G1′).

### (G2) Heat Curable Agent Having the Reactive Double Bond Group

Heat curable agent having the reactive double bond group (G2) is the heat curable agent having a polymerizable carbon-carbon double bond. As the reactive double bond group having heat curable agent (G2), a vinyl group, an allyl group, a methacryloyl group or so are preferably exemplified, and said methacryloyl group is more preferably exemplified.

In addition, the heat curable agent (G2) includes the functional group reactive with the epoxy group in addition to the abovementioned reactive double bond group. As the functional group reactive with the epoxy group, phenolic hydroxy groups, alcoholic hydroxy groups, amino groups, carboxyl groups and acid anhydrides are preferably exemplified. Among all, phenolic hydroxy groups, alcoholic hydroxy groups and amino groups are more preferably exemplified, and phenolic hydroxy groups are the most preferably exemplified.

As heat curable agent (G2) having the reactive double bond group, for instance, compounds, in which a part of the hydroxy group of the phenol resin is substituted with the group including the reactive double bond group, or compounds, in which the group including the reactive double bond group is directly bonded to the aromatic ring of the phenol resin, or so may be exemplified. As the phenol resin, novolak type phenol resin shown by the following formula (Chem. 7), dicyclopentadiene type phenol resin shown by the following formula (Chem. 8), polyfunctional based phenol resin shown by the following formula (Chem. 9) are exemplified, and said novolak type phenol resin is preferable. Therefore, as heat curable agent having the reactive double bond group (G2), compounds in which a part of the hydroxyl group of novolak type phenol resin is substituted with the group including the reactive double bond group, or compounds in which the group including the reactive double bond group is directly bonded to the aromatic ring of the novolak type phenol resin is preferable.

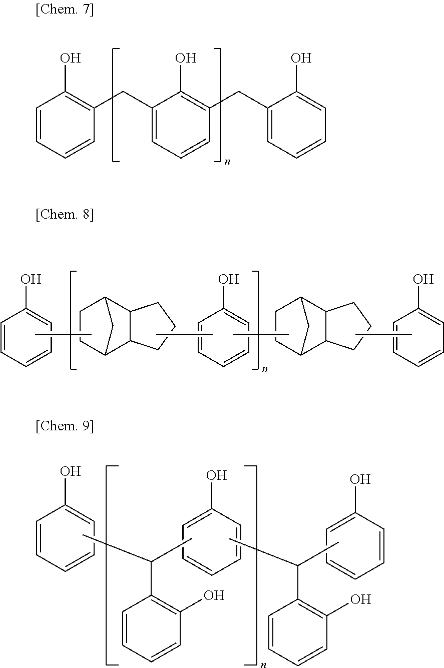

As more preferable example of heat curable agent having the reactive double bond group (G2), a compound having a structural unit in which the reactive double bond group is introduced to a part of repetition unit including phenolic hydroxy groups such as the following formula (a), and including repetition unit having groups including the reactive double bond group such as the following formula (b) or (c). The most preferable example of heat curable agent (G2) having the reactive double bond group (G2) includes repetition unit of the following formula (a) and repetition unit of the following formula (b) or (c).

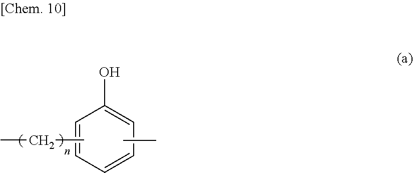

[“n” in the formula is 0 or 1.]

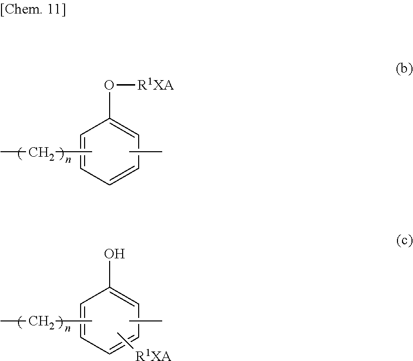

[“n” in the formula is 0 or 1. “R¹” is a hydrocarbon group in which carbon number is 1 to 5 and may include hydroxy group. “X” is —O— or —NR²—(R² is hydrogen or methyl). “R¹X” is a single bond. “A” is (meth)acryloyl group.]

The phenolic hydroxy group included in the repetition unit (a) is the functional group reactive with the epoxy group and function as the curing agent, which is subjected to the curing reaction with the epoxy group of the epoxy compound during heat curing of the film for resin film formation. The reactive double bond group included in repetition units (b) and (c) improve compatibility of acrylic polymer (F1) and heat curable component (G), and form the three dimensional network structure in the film for resin film formation by addition polymerization of the reactive double bond groups mutually. As a result, a cured product (the resin film) of the film for resin film formation becomes tougher, and thus, reliability of semiconductor device improves. In addition, the reactive double bond group included in repetition units (b) and (c) is subjected to polymer cure when the film for resin film formation is energy ray cured and decreases adhesiveness between the film for resin film formation and the pressure-sensitive adhesive sheet.

Content ratio of repetition unit shown by the above formula (a) in heat curable agent (G2) is preferably 5 to 95 moles %, more preferably 20 to 90 moles % and the most preferably 40 to 80 moles %. Ratio of repetition unit shown by the above formula (b) or (c) in total is preferably 5 to 95 moles more preferably 10 to 80 moles % and the most preferably 20 to 60 moles %.

### (G2′) Heat Curable Agent not Having the Reactive Double Bond Group

As heat curable agent (G2′) not having the reactive double bond group, a compound having two or more functional groups reactive with the epoxy group in a molecule can be mentioned. As the functional group, phenolic hydroxy groups, alcoholic hydroxy groups, amino groups, carboxyl groups, acid anhydrides or so may be mentioned. Among all, phenolic hydroxy groups, amino groups, acid anhydrides or so are preferably mentioned, and phenolic hydroxy groups and amino groups are more preferably mentioned.

Concrete example of the heat curable agent having amino group (amine based heat curable agent) is DICY (dicyandiamide).

As concrete examples of the heat curable agent having phenolic hydroxy groups (a phenol-based heat curable agent), polyfunctional based phenol resin, biphenol, novolak type phenol resin, dicyclopentadiene based phenol resin, aralkylphenol resin or so may be mentioned.

These may be used alone, or by combining two or more kinds thereof.

Number-average molecular weight of the heat curable agents (G2) and (G2′) mentioned above is preferably 40 to 30,000, more preferably 60 to 10,000, and the most preferably 80 to 10,000.

Content amount of heat curable agents [(G2) and (G2′)] in the film for resin film formation is preferably 0.1 to 500 parts by mass, and more preferably 1 to 200 parts by mass, with respect to 100 parts by mass of epoxy compounds [(G1) and (G1′)]. In case when content amount of the heat curable agent is small, adhesiveness may not be obtained due to curing insufficiency. In addition, content amount of heat curable agents [(G2) and (G2′)] is preferably 1 to 50 parts by mass and more preferably 2 to 40 parts by mass with respect to 100 parts by mass of polymer component (F). In case when content amount of the heat curable agent is small, adhesiveness may not be obtained due to curing insufficiency.

Ratio of heat curable component (G) (a total of the epoxy compound and the heat curable agent [(G1)+(G1′)+(G2)+(G2′)]) in a total mass of the film for resin film formation is preferably less than 50 mass %, more preferably 1 to 30 mass % and the most preferably 5 to 25 mass %. Further, heat curable component (G) is included within a range of preferably 1 part by mass or more and less than 105 parts by mass, more preferably 1 to 100 parts by mass, further preferably 3 to 60 parts by mass, and the most preferably 3 to 40 parts by mass, with respect to 100 parts by mass of polymer component (F). In particular, in case when content amount of heat curable component (G) is small, such as 3 to 40 parts by mass with respect to 100 parts by mass of polymer component (F), the following effect can be obtained. In case when the film for resin film formation is used as the die bonding adhesive film to adhere to a die placement part of a semiconductor chip, even when the film for resin film formation is heated to a high temperature after the film for resin film formation is fixed to the semiconductor chip and the chip is temporary adhered to a die placement part via the film for resin film formation and before heat curing the film for resin film formation, occurrence of voids in the film for resin film formation during heat curing process can be decreased. In case when content amount of heat curable component (G) is excessive, sufficient adhesiveness may not be obtained.

### (G3) Curable Catalyst

Curable catalyst (G3) may be used to regulate the speed of the curing of the film for resin film formation. Heat curable catalyst (G3) is preferably used particularly when the epoxy based heat curable component is used as the heat curable component (G).

As the preferable curable catalyst, tertiary amines such as triethylene diamine, benzyldimethyl amine, triethanol amine, dimethylamino ethanol, tris(dimethylaminomethyl)phenol or so; imidazoles such as 2-methylimidazole, 2-phenylimidazole, 2-phenyl-4-methylimidazole, 2-phenyl-4,5-dihydroxymethylimidazole, 2-phenyl-4-methyl-5-hydroxymethylimidazole or so; organic phosphines such as tributylphosphine, diphenylphosphine, triphenylphosine or so; tetraphenylboron salt such as tetraphenylphosphoniumtetraphenylborate, triphenylphosphinetetraphenylborate or so may be mentioned. These may be used alone or by mixing two or more thereof.

In case of using curable catalyst (G3), curable catalyst (G3) is preferably 0.01 to 10 parts by mass, and more preferably 0.1 to 2.5 parts by mass, with respect to 100 parts by mass of the heat curable component (G) in total [(G1)+(G1′)+(G2)+(G2′)]. In case of using the film for resin film formation as the die bonding adhesive film to adhere the semiconductor chip to the die placement part, with the inclusion of curable catalyst (G3) within the above mentioned range, an excellent adhesiveness can be exhibited even when exposed under high temperature and high humidity condition, and also high package reliability can be attained even in case of being exposed under harsh reflow condition. In addition, in case of using the film for resin film formation as a film for protective film formation for forming a film protecting the backside of a face-down type semiconductor chip, with the inclusion of curable catalyst (G3) within the above range, the backside protection function of the chips are superior. In case when content amount of curable catalyst (G3) is less, sufficient adhesiveness may not be obtained.

The following components other than binder component having the reactive double bond group may be included in the film for resin film formation.

### Filler (H)

The film for resin film formation may include filler (H). By blending filler (H) in the film for resin film formation, a thermal expansion coefficient of the resin film obtained by curing the film for resin film formation is possible to regulate, and reliability of the semiconductor device can be improved by optimizing the thermal expansion coefficient of the resin film with respect to the work. Further, moisture permeability of the resin film can be reduced.

In addition, in case of making the resin film obtained by curing the film for resin film formation of the invention to function as the protective film of the work or of chips which the work is separated, by carrying out the laser marking to the protective film, filler (H) is exposed at a scraped-off portion by the laser beam and a reflected light is scattered which show a color close to white. Thereby, in case the film for resin film formation includes coloring agent (I) which will be described in below, the contrast between the laser marking part and other part is generated thereby there is an effect to make the printing clearer.

As the preferable filler (H), powders such as silica, alumina, talc, calcium carbonate, titanium oxide, iron oxide, silicon carbide, boron nitride or so, a beads of which these has been made into spherical form, a single crystal fiber and glass fiber or so may be mentioned. Among these, silica filler and alumina filler are preferable. The above mentioned filler (H) may be used alone or by mixing two or more thereof.

In order to ensure the above effect, as the content range of filler (H), it is preferably 1 to 80 mass % and more preferably 20 to 75 mass %, with respect to entire mass amount of the film for resin film formation. In addition, in case of using the film for resin film formation as the film for protective film formation for forming the film protecting the backside of the face-down type semiconductor chip, in view of improving the backside protection function of the chips, content of filler (H) is preferably 40 to 70 mass % in particular with respect to entire mass of the film for resin film formation.

The surface of filler (H) of the invention is preferably modified by the compound having the reactive double bond group. Hereinafter, the filler on which the surface thereof is modified by the compound having the reactive double bond group is described as “the filler having the reactive double bond group on its surface”.

The reactive double bond group included in the filler (H) is preferably a vinyl group, an allyl group or (meth)acryloyl group.

As the untreated filler used for the filler having the reactive double bond group on its surface, calcium silicate, magnesium hydroxide, aluminum hydroxide, titanium oxide, talc, mica, clay or so may be mentioned. Among all, silica is preferable. Silanol groups of silica effectively acts as bonding with the silane coupling agent mentioned below.

The filler having the reactive double bond group on its surface is obtained such as by surface treating the surface of the untreated filler with the coupling agent having the reactive double bond group.

The abovementioned coupling agent having the reactive double bond group is not particularly limited. As the coupling agent, the coupling agent having vinyl group, the coupling agent having styryl group, the coupling agent having (meth)acryloxy group or so may be mentioned. The above mentioned coupling agent is preferably silane coupling agent.

As concrete examples of the abovementioned coupling agent, vinyltrimethoxysilane, vinyltriethoxysilane, p-styryltrimethoxysilane, 3-metacryloxy propyldimethoxysilane, 3-meta-cryloxy propyltrimethoxysilane, 3-meta-cryloxy propyltriethoxysilane, 3-meta-cryloxy propylmethyldiethoxysilane, 3-acryloxy propyltrimethoxysilane or so may be mentioned. As commercial products thereof, KBM-1003, KBE-1003, KBM-1403, KBM-502, KBM-503, KBE-502, KBE-503, KBM-5103 (All of the above are made by Shin-Etsu Chemical Co., Ltd.) or so may be mentioned.

The method for surface treating the above mentioned filler by the abovementioned coupling agent, is not particularly limited depending on the above mentioned coupling agent. As such method, for instance, a dry method, wherein the untreated filler is added to a high speed stirring mixer such as Henschel mixer, V-shaped mixer or so, and while stirring, the coupling agent is added directly or added by dissolving and dispersing in an alcohol aqueous solution, an organic solvent or an aqueous solution, can be mentioned. In addition, a slurry method wherein the coupling agent in slurry of the untreated filler is added, a direct treatment method such as a spray method wherein the coupling agent is added by spray after drying the untreated filler or so, integral blending methods wherein the untreated filler and the acryl based polymer are mixed during preparation of the abovementioned composition, and the coupling agent is directly added while mixing, or so may be mentioned.

Preferable lower limit of the coupling agent surface treating 100 parts by mass of the abovementioned filler is 0.1 parts by mass, while preferable upper limit thereof is 15 parts by mass. In case when the amount of the coupling agent is less than 0.1 parts by mass, the untreated filler may not be sufficiently surface treated by the abovementioned coupling agent and there is a chance that the above mentioned effect cannot be obtained.

The filler having the reactive double bond group on its surface is superior in affinity with binder component having the reactive double bond group, and is able to uniformly disperse the film for resin film formation.

The filler having the reactive double bond group on its surface is included preferably less than 50 mass %, more preferably 1 to 30 mass % and the most preferably 5 to 25 mass %, with respect to entire mass of the film for resin film formation. Further, with respect to 100 parts by mass of the binder component, the filler having the reactive double bond group on its surface is included within a range of preferably 5 parts by mass or more and less than 100 parts by mass, more preferably 8 to 60 parts by mass and further preferably 10 to 40 parts by mass. In case when amount of the filler having the reactive double bond group on its surface is excessive, attachment ability to the work or adhesiveness to the substrate may become inferior. In case when amount of the filler having the reactive double bond group on its surface is small, there is a chance that addition effect of the filler may not be obtained.

In case when the film for resin film formation include the filler having the reactive double bond group on its surface within the above range, said film for resin film formation, even in uncured or semicured state, shows elastic modulus which is resistant to the vibration during wire bonding. Thus, the chips are not subjected to vibration or displacement during wire bonding and an effect to safely perform wire bonding is heightened.

An average particle diameter of filler (H) is preferably within the range of 0.01 to 10 μm and more preferably 0.01 to 0.2 μm. In case when the average particle diameter of the filler is within the above range, adhesiveness can be exhibited without deteriorating the attachment ability of the work. In addition, in case when the semiconductor chips are used as the adhesive film for the die bonding to adhere to the die placement part, an effect for improving packaging reliability can be remarkably obtained. In case when the abovementioned particle diameter is too large, the sheet face condition is deteriorated and a defect, in which thickness in the face of the film for resin film formation is ununiform, may be occurred.

Note that the above described “average diameter” is obtained by a particle size analyzer (made by Nikkiso Co., Ltd., device name: Nanotrac 150) using the dynamic light scattering method.

The following reasons are assumed for remarkably obtaining the packaging reliability improving effect when the average particle diameter of the filler is within the above range.

In case when the average particle diameter of the filler is large, the structure formed by components, other than the filler which fills between fillers, also becomes large. Cohesiveness of the component other than the filler is lower than that of the filler. There is a concern that, once a breakage occurs in the component other than the filler, said breakage may spread over a wide range in case when the structure formed by the component other than the filler is large. While when the filler is a fine material, the structure formed by the component other than the filler also has a fine structure. Therefore, even when the breakage is occurred in the component other than the filler, the filler included in the structure prevents progress of the breakage. As a result, the breakage tends not to spread widely. Further, in the invention, the reactive double bond group, such as methacryloxy group or so, included in the filler and the reactive double bond group included in the component other than the filler, such as the binder component, may form bonding. In case when the filler is the fine material, contact area of the filler and the component other than the filler becomes large. Consequently, the bonding between the filler and the binder component tends to increase.

### Coloring Agent (I)

The film for resin film formation can be blended with the coloring agent (I). By blending the coloring agent, when the semiconductor devices are incorporated to the machines, the infrared ray or so generated by the surrounding devices can be blocked, thus the malfunction of the semiconductor device caused thereby can be prevented. Also, if the resin film is marked by means of laser marking or so, there is an effect that the marks such as the letters and symbols or so become visible. That is, for the semiconductor device or the semiconductor chip formed with the resin film, usually the product number or so is printed on the surface of the resin film by laser marking method (the method of printing by grinding the surface of the protective film by the laser light), however since the resin film includes the coloring agent (I), the sufficient contrast between the area of the resin film which is ground off by the laser, and those not ground off can be generated, hence the visibility is improved.

As the coloring agent, the organic or inorganic pigment and die are used. Among these, a black pigment is preferable from the point of the blocking property of the electromagnetic wave or the infrared ray. As for the black pigment, carbon black, manganese dioxide, aniline black, and activated carbon or so may be used, but it is not limited thereto. The carbon black is particularly preferable from the point of improving the reliability of the semiconductor device. The coloring agent (I) may be used alone, or by combining two or more thereof.

The blending amount of the coloring agent (I) is preferably 0.1 to 35 mass %, more preferably 0.5 to 25 mass % and particularly preferably 1 to 15 mass % with respect to the entire mass of the film for resin film formation.

### Coupling Agent (J)

The coupling agent (J) having the functional group reacting with the inorganic compound and the functional group reacting with the organic functional group may be used to improve the adhesiveness and the contact of the film for resin film formation against the work, and/or the cohesiveness of the film for resin film formation. Also, by using the coupling agent (J), without compromising the heat resistance of the resin film, the water resistance thereof can be improved. As such coupling agent, a titanate based coupling agent, an aluminate based coupling agent, and a silane coupling agent or so may be mentioned. Among these, the silane coupling agent is preferable.

As the silane coupling agent, the silane coupling agent is preferably used wherein the functional group which reacts with the organic functional group thereof is the group which reacts with the functional group in polymer component (F), heat curable component (G) or so.

As such silane coupling agent, low molecular weight silane coupling agents having 2 or 3 alkoxy groups such as γ-glycidoxypropyltrimethoxy silane, γ-glycidoxypropyltriethoxy silane, γ-glycidoxypropylmethyldiethoxy silane, β-(3,4-epoxycyclohexyl)ethyltrimethoxy silane, γ-(methacryloxypropyl)trimethoxy silane, γ-aminopropyltrimethoxy silane, N-6-(aminoethyl)-γ-aminopropyltrimethoxy silane, N-6-(aminoethyl)-γ-aminopropylmethyldiethoxy silane, N-phenyl-γ-aminopropyltrimethoxy silane, γ-ureidepropyltriethoxy silane, melcaptopropyltrimethoxy silane, γ-melcaptopropylmethyldimethoxy silane, methyltrimethoxy silane, methyltriethoxy silane, vinyltrimethoxy silane or so, bis(3-triethoxysilylpropyl)tetrasulphone, vinyltriacetoxy silane, imidazole silane or so may be mentioned. Further, oligomer types, which are products obtained by the condensation of hydrolysis and dehydration concentration of the alkoxy groups in the low molecular weight silane coupling agent having 2 or 3 alkoxy groups mentioned above or low molecular weight silane coupling agents having 4 alkoxy groups, may be mentioned. In particular, among the low molecular weight silane coupling agents, oligomers which are products concentrated by dehydration concentration of the low molecular weight silane coupling agent having 2 or 3 alkoxy groups and low molecular weight silane coupling agents having 4 alkoxy groups are preferable since they are rich in reactivity and has sufficient number of organic functional groups. For instance, an oligomer which is a copolymer of 3-(2,3-epoxypropoxy)propylmethoxysiloxane and dimethoxysiloxane can be mentioned as an example thereof.

These may be used alone, or by combining two or more thereof.

The silane coupling agent is included in the ratio usually of 0.1 to 20 parts by mass, preferably 0.2 to 10 parts by mass and more preferably 0.3 to 5 parts by mass with respect to 100 parts by mass of binder component. If the content of the silane coupling agent is less than 0.1 parts by mass, there is a chance that the above mentioned effect cannot be obtained, and if it exceeds 20 parts by mass, it may become a cause of the outgas generation.

### Crosslinking Agent (K)

Crosslinking agent (K) may be added to regulate initial adhesiveness and the cohesive strength of the film for resin film formation. Note, in order to compound the crosslinking agent, the reactive functional group may be added to acrylic polymer (F1) mentioned above.

The organic polyvalent isocyanate compounds, organic polyvalent imine compounds or so may be mentioned as crosslinking agent (K), and the same examples shown as crosslinking agent (B) in the abovementioned pressure-sensitive adhesive layer may be exemplified.

In case when isocyanate based crosslinking agent is used, acrylic polymer (F1) having hydroxy group as the reactive functional group is preferably used. In case when the crosslinking agent has isocyanate group and acrylic polymer (F1) includes the hydroxyl group, the reaction between said crosslinking agent and acrylic polymer (F1) occurs and the crosslinking structure can be easily introduced to the film for resin film formation.

In case of using crosslinking agent (K), crosslinking agent (K) is generally 0.01 to 20 parts by mass, preferably 0.1 to 10 parts by mass, and more preferably 0.5 to 5 parts by mass, with respect to 100 pars by mass of acrylic polymer (F1).

### Photopolymerization Initiator (L)

Photopolymerization initiator (L) may be added to the film for resin film formation. With the inclusion of the photopolymerization initiator, in case when the composite sheet for resin film formation of the invention is used as a dicing.die bonding sheet, the reactive double bond group in the binder component, in some cases, the reactive double bond group in the filler is subjected to reaction and can be preliminary cured by irradiating ultra violet ray before dicing process after adhering to wafer. The film for resin film formation before curing is relatively softened by performing the preliminary curing. Thus, said film has good attachment property to the wafer and has an appropriate hardness when dicing; and an adhesion of the film for resin film formation to the dicing blade and other defects can be prevented. In addition, it becomes possible to control release property of the interface between the pressure-sensitive adhesive sheet and the film for resin film formation. Further, hardness of the preliminary cured state is higher than that of the uncured state, and that stability during wire bonding improves.

In concrete, the same examples of the abovementioned photopolymerization initiator (E) can be exemplified as photopolymerization initiator (L).

In case of using photopolymerization initiator (L), the blending ratio may be suitably determined based on a total amount of the reactive double bond group on the surface of the filler and the reactive double bond group of the binder component. It is not particularly limited; however, photopolymerization initiator (L) is generally 0.1 to 10 parts by mass and preferably 1 to 5 parts by mass, with respect to 100 parts by mass of the total of the polymer component having the reactive double bond group, the heat curable component having the reactive double bond group, and the filler. In case when content of photopolymerization initiator (L) is lower than the above range, sufficient reaction may not be obtained due to insufficient photopolymerization, while higher than the above range, residues which do not contribute to the photopolymerization may generate and curable property of the film for resin film formation becomes insufficient.

### General Additives (M)

Various additives may be blended depending on the needs into the film for resin film formation besides the above described. As for the various additives, a leveling agent, a plasticizer, an antistatic agent, an antioxidizer, an ion scavenger, a gettering agent, a chain transfer agent, a release agent or so may be mentioned.

The film for resin film formation is obtained for example by using the composition (a composition for resin film formation) obtained by mixing the above mentioned each component in an appropriate ratio. The composition for resin film formation may be diluted with the solvent in advance, or may be added to the solvent during the mixing. Also, when using the composition for resin film formation, it may be diluted with the solvent.

As such solvent, ethyl acetate, methyl acetate, diethyl ether, dimethyl ether, acetone, methylethyl ketone, acetonitrile, hexane, cyclohexane, toluene, heptane or so may be mentioned.

The film for resin film formation possesses the initial adhesiveness (i.e. the pressure sensitive adhesiveness or heat adhesiveness) and the curable property. In case when the film for resin film formation has the pressure sensitive adhesiveness, the film can be pressed and attached to the work in the uncured state. Further, in case when the film for resin film formation has the heat adhesiveness, said film for resin film formation can be heated and attached when pressing to the work. The heat adhesiveness of the invention means that it becomes adhesive to the work by softening with heat, although it is not pressure sensitive at a normal temperature.

The film for resin film formation can provide the resin film which eventually shows high impact resistance ability though curing, thus, the adhesive strength or the protection function under severe conditions of high temperature and high humidity are superior. The film for resin film formation may be a single layer structure or a multilayer structure.

The film for resin film formation, in which filler having the reactive double bond group on its surface is blended, is superior in dispensability of the filler and the filler is uniformly dispersed. Thus, in case of using as the die bonding adhesive film, chips are bonded and the wire bonding can be stably processed with less deformation of the film for resin film formation even at a high temperature of performing the wire bonding. The resin film having high impact resistance can be eventually provided through heat curing. The film is also superior in the shear strength, and sufficient adhesive property can be maintained even under severe conditions of high temperature and high humidity.

Thickness of the film for resin film formation is preferably 1 to 100 μm, more preferably 2 to 90 μm, and the most preferably 3 to 80 μm. By determination of thickness of the film for resin film formation within the above range, the film for resin film formation functions as a high reliable adhesive agent or the protective film.

### [The Composite Sheet for Resin Film Formation]

The structure of the composite sheet for resin film formation of the invention composing the above each layer is shown by FIGS. 1 to 3. As shown in FIGS. 1 to 3, the composite sheet for resin film formation 10 has pressure-sensitive adhesive sheet 3, having pressure-sensitive adhesive layer 2 on base 1, and the heat curable film for resin film formation 4 mounted on pressure-sensitive adhesive sheet 3. Film for resin film formation 4 is formed in a releasable manner on pressure-sensitive adhesive layer 2, and is not particularly limited as long as the film has roughly the same shape as the work or the shape which can completely include the shape of the work. For instance, as shown in FIGS. 1 and 2, the film for resin film formation of the composite sheet for resin film formation may take pre-forming constitution wherein the film for resin film formation is prepared to have roughly the same shape as the work or the shape which can completely include the shape of the work, and stacked on the pressure-sensitive adhesive sheet having larger size than the film for resin film formation. Further, as shown in FIG. 3, the film for resin film formation may have the same shape as the pressure-sensitive adhesive sheet.

The shape of the composite sheet for resin film formation is not limited to sheet shape, but it may be a belt shape, or these may be rolled up.

The composite sheet for resin film formation is adhered to the work, and in some case a predetermined processing such as dicing or so may be carried to the work on the composite sheet for resin film formation. Then, the pressure-sensitive adhesive sheet is released while the film for resin film formation is adhered to the work. That is, the film for resin film formation is used for the process including the step of transferring said film for resin film formation to the work from the pressure-sensitive adhesive sheet.

In case the dicing process is performed to the work on the composite sheet for resin film formation, the composite sheet for resin film formation function as the dicing sheet for supporting the work during the dicing step, the adhesiveness between the pressure-sensitive adhesive sheet and the film for resin film formation is maintained, and the chip with the film for resin film formation is suppressed from being released from the pressure-sensitive adhesive sheet during the dicing step. When the composite sheet for resin film formation function as the dicing sheet for supporting the work during the dicing step, there is no need to separately attach the dicing sheet to the wafer with the film for resin film formation during the dicing step, thus the production steps of the semiconductor device can be simplified.

In case the film for resin film formation takes such pre-forming constitution, the film for resin film formation may take the first or second constitution mentioned in following. Hereinafter, each constitution of the composite sheet for resin film formation 10 will be explained based on FIG. 1 and FIG. 2.

In the first constitution, as shown in FIG. 1, pressure-sensitive adhesive sheet 3 formed with pressure-sensitive adhesive layer 2 on base 1 is formed in a releasable manner on one face of film for resin film formation 4. In case of employing the first constitution, the composite sheet for resin film formation 10 is attached to jig 7 by pressure-sensitive adhesive layer 2 of pressure-sensitive adhesive sheet 3 at the outer peripheral part thereof.

In the second constitution, as shown in FIG. 2, jig adhesive layer 5 is separately provided to area which does not overlap with the film for resin film formation 4 on the pressure-sensitive adhesive layer 2 of the composite sheet for resin film formation 10. As the jig adhesive layer, the pressure-sensitive adhesive material made of the pressure-sensitive adhesive single layer, the pressure-sensitive adhesive material composed of the base and the pressure-sensitive adhesive layer, the both sided pressure-sensitive adhesive material having a core material or so can be used.

The jig adhesive layer is a ring shaped, has a cavity part (internal opening) and has a size fixable to the jigs such as a ring frame. In concrete, the inner diameter of the ring frame is smaller than the outer diameter of the jig adhesive layer. Further, the inner diameter of the ring frame is relatively larger than the inner diameter of the jig adhesive layer. Note, the ring frame is generally a molded body of metals or plastics.

In case when the pressure-sensitive adhesive material composed of the pressure-sensitive adhesive layer alone is the jig adhesive layer, although the pressure-sensitive adhesive agent forming the pressure-sensitive adhesive layer is not particularly limited, it is preferably composed of the acrylic pressure-sensitive adhesive agent, the rubber based adhesive pressure-sensitive agent or the silicone pressure-sensitive adhesive agent. Among all, considering re-reasable property of the ring frame, the acrylic pressure-sensitive adhesive agent is preferable. The above-mentioned pressure-sensitive adhesive agents can be used alone or two or more can be combined.

Thickness of the pressure-sensitive adhesive layer is preferably 2 to 20 μm, more preferably 3 to 15 μm, and the most preferably 4 to 10 μm. In case when thickness of the pressure-sensitive adhesive agent layer is less than 2 μm, sufficient adhesiveness may not be expressed. In case the thickness of the pressure-sensitive adhesive layer is more than 20 μm, the ring frame may be contaminated by the residues of the pressure-sensitive adhesive agent on the ring frame when releasing from the ring frame.

In case when the pressure-sensitive adhesive material composed of the base and the pressure-sensitive adhesive layer is the jig adhesive layer, the ring frame is adhered to the pressure-sensitive adhesive layer composing the pressure-sensitive adhesive material.

The pressure-sensitive adhesive agent forming the pressure-sensitive adhesive layer is the same with the pressure-sensitive adhesive agent forming the pressure-sensitive adhesive layer of the pressure-sensitive adhesive material composed of the above-mentioned pressure-sensitive adhesive layer alone. Further, thickness of the pressure-sensitive adhesive layer is also the same.

The base constituting the jig adhesive layer is not particularly limited; however, for example polyolefin film, polyvinyl chloride film and polyethylene terephthalate film, such as polyethylene film, polypropylene film, ethylene vinyl acetate copolymer film, ethylene(meth)acrylate copolymer film, ionomer resin film can be mentioned. Among all, considering expandability, polyethylene film and polyvinyl chloride film are preferable, and polyvinyl chloride film is the most preferable.

Thickness of the base is preferably 15 to 200 μm, more preferably 30 to 150 μm and the most preferably 40 to 100 μm. In case when thickness of the base is less than 15 μm, deformation may occur when the composite sheet for resin film formation and the jig adhesive layer are adhered and the formation may not be maintained. In case when thickness of the base exceeds 200 μm, the occurrence of the rolling mark caused by the level difference may occur when the composite sheet for resin film formation is made to a roll-form for core material.

In the composite sheet for resin film formation of the invention, inner diameter of the jig adhesive layer is preferably 0 to 10 mm larger than the diameter of the work on which the film for resin film formation is attached. Namely, the inner diameter of the jig adhesive layer is the same with the diameter of the work, or the inner diameter of the jig adhesive layer is preferably longer than the diameter of the work by more than 0 mm and 10 mm or less. In addition, it is more preferable that the difference between inner diameter of the jig adhesive layer and the diameter of the work is 0 to 5 mm.

According to the manufacturing process of the semiconductor device using the composite sheet for resin film formation of the invention, the chips may be obtained by dicing (cutting and separating) the work by the dicing blade. At this time, with the dicing blade, the film for resin film formation, the pressure-sensitive adhesive layer, or the jig adhesive layer at peripheral part of the work may be cut, and the cut-in may be caused. By setting the difference between the inner diameter of the jig adhesive layer and the diameter of the work within the above range, the cut-in part of the film for resin film formation or the pressure-sensitive adhesive layer in the composite sheet for resin film formation during the dicing may become difficult to turn-over. Further, the cut-in parts do not break easily and can be prevented from being small pieces and scatter. Thus, the film for resin film formation or the pressure-sensitive adhesive layer is not adhered on the upper face of the chips obtained from dicing the work, and chips are difficult to be contaminated. Further, in case when the difference between the inner diameter of the jig adhesive layer and the diameter of the work is suppressed within the above range, the contamination of the chips can be prevented as mentioned above, even when the film for resin film formation gives little tack.

Meanwhile, the chips are likely to be contaminated when the difference between the inner diameter of the jig adhesive layer and the diameter of the work exceeds 10 mm. The work may be adhered to the jig adhesive layer when the difference mentioned above is less than 0 mm, and the accuracy of the adhering device may be required in order not to adhere the work to the jig adhesive layer in case when the difference mentioned above is less than 1 mm. Thus, the inner diameter of the jig adhesive layer is larger than the diameter of the attached work by 1 to 10 mm.

Diameter of the work mentioned above is preferably 100 to 450 mm, in concrete, wafers having the diameter of 100 mm, 150 mm, 200 mm, 300 mm, 400 mm and 450 mm may be used.

Further, in case when the both sided pressure-sensitive adhesive material having the core material is the jig adhesive layer, said both sided pressure-sensitive adhesive material is composed of the core material, the pressure-sensitive adhesive layer for lamination formed on one side thereof, and the pressure-sensitive adhesive layer for fixing formed on the other side thereof. The pressure-sensitive adhesive layer for lamination is laminated with the pressure-sensitive adhesive layer of the composite sheet for resin film formation, and the pressure-sensitive adhesive layer for fixing is attached to the ring frame during the dicing process.

As the core material of the both sided pressure-sensitive adhesive material, the same with the base of the abovementioned pressure-sensitive adhesive material can be mentioned. Among all, considering the expandability, polyolefin film and the plasticized polyvinyl chloride film are preferable.

Thickness of the core material is generally 15 to 200 μm, preferably 30 to 150 μm and more preferably 40 to 100 μm. In case when thickness of the core material is less than 15 μm, the formation may not be maintained when the composite sheet for resin film formation and the both sided pressure-sensitive adhesive material are adhered. In case when thickness of the core material exceeds 200 μm, the occurrence of the rolling mark caused by the level difference may occur when the composite sheet for resin film formation is made to a roll-form for storage and transportation.

The pressure-sensitive adhesive layer for lamination and the pressure-sensitive adhesive layer for fixing of the both sided pressure-sensitive adhesive material may be the layers composed of the same pressure-sensitive adhesive agent or of different pressure-sensitive adhesive agents. They are suitably selected in order to make the adhesiveness between the pressure-sensitive adhesive layer for fixing and the ring frame is smaller than the pressure-sensitive adhesiveness between the adhesive layer of the composite sheet for resin film formation and the pressure-sensitive adhesive layer for lamination. As such pressure-sensitive adhesive agent, the pressure-sensitive acrylic adhesive agent, the rubber based pressure-sensitive adhesive agent, the silicone pressure-sensitive adhesive agent or so may be mentioned. Among all, considering re-reasable property from the ring frame, the acrylic pressure-sensitive adhesive agent is preferable. The pressure-sensitive adhesive agent forming the pressure-sensitive adhesive layer for fixing may be used alone or two or more thereof can be combined. The same applies to the pressure-sensitive adhesive layer for lamination.

Thickness of the pressure-sensitive adhesive layer for lamination and the same of the pressure-sensitive adhesive layer for fixing are the same with the thickness of the pressure-sensitive adhesive layer of the pressure-sensitive adhesive material mentioned above.

By constituting the composite sheet for resin film formation as such first and second constitutions, the composite sheet for resin film formation can be adhered to the jig such as the ring frame or so by sufficient adhesiveness of the pressure-sensitive adhesive layer or the jig adhesive layer in the surrounding area of the film for resin film formation.

In case the film for resin film formation does not take the pre-forming constitution, namely, in case when the film for resin film formation 4 and the pressure-sensitive adhesive sheet 3 are formed to the same shape as shown in FIG. 3, jig adhesive layer 5 may be set at the outer peripheral part of the surface of the film for resin film formation 4. The same as mentioned above can be used for the jig adhesive layer. Note, in case when the both sided pressure-sensitive adhesive material having the core material is used as the jig adhesive layer, the pressure-sensitive adhesive layer for lamination is laminated with the film for resin film formation of the composite sheet for resin film formation.

A cover film may be temporarily adhered to a face of the film for resin film formation, which is the opposite to the face attached to the pressure-sensitive adhesive sheet. The cover film may cover the pressure-sensitive adhesive layer or the jig adhesive layer. As the cover film, for example polyethylene film, polypropylene film, polybutene film, polybutadiene film, polymethylpentene film, polyvinyl chloride film, vinyl chloride copolymer film, polyethylene terephthalate film, polyethylene naphthalate film, polybutyleneterephthalate film, polyurethane film, ethylene vinyl acetate copolymer film, ionomer resin film, ethylene′(meth)acrylate copolymer film, ethylene′(meth)acrylate copolymer film, polystyrene film, polycarbonate film, polyimide film, fluorine resin film or so is used. Also, the crosslinked film thereof may be used as well. Further, it may be a laminated film thereof

The surface tension of the face of the cover film contacting with the film for rein film formation is preferably 40 mN/m or less, more preferably 37 mN/m or less, and particularly preferably 35 mN/m or less. The lower limit is usually 25 mN/m or so. The cover film with such low surface tension can be obtained by selecting the material appropriately, or by carrying out the release treatment by coating the release agent to the surface of the cover film.

As the release agent used for the release treatment, the release agent of an alkyd based, a silicone based, a fluorine based, an unsaturated polyester based, a polyolefin based, a waxed based or so may be used; and the alkyd based, the silicone based, and the fluorine based release agent are preferable since these have heat resistance.

In order to carry out the release treatment to the surface of the film or so which becomes the base of the cover film using the above mentioned release agent, the release agent may be used without the solvent, or by diluting with the solvent or by emulsifying, then coating by a gravure coater, a Meyer bar coater, an air knife coater, a roll coater or so; then the release agent layer may be formed by curing by placing the cover film coated with the release agent under the ambient temperature or under a heating condition, or applying the electron beam.

Also, the surface tension of the cover film may be regulated by stacking the films using a wet lamination or dry lamination, a thermofusion lamination, a melt extrusion lamination, and a coextrusion processing or so. Namely, film, in which the surface tension of at least one face is within the preferable range as a face contacting the film for resin film formation of the cover film, is laminated with the other film by making said face contacting the film for resin film formation and produces the multilayered body, which may be the cover film.

Thickness of the cover film is generally 5 to 300 preferably 10 to 200 μm and the most preferably 20 to 150 μm or so.

Such film for resin film formation of the composite sheet for resin film formation function as the die bonding adhesive film for adhering the chips, obtained by separating the work, to the die placement part or as the film protecting the backside of the face-down type semiconductor chip.

### [The Manufacturing Method of the Composite Sheet for Resin Film Formation]

Manufacturing method of the composite sheet for resin film formation will be concretely described below referring to the composite sheet for resin film formation shown in FIG. 1, the composite sheet for resin film formation of the present invention is not limited to thereof.

First, the pressure-sensitive adhesive layer is formed on the surface of the base and the pressure-sensitive adhesive sheet is obtained. The method to obtain the pressure-sensitive adhesive layer on the surface of the base is not particularly limited.

For instance, in case of forming pressure-sensitive adhesive layer by the non-energy ray curable pressure-sensitive adhesive composition, the non-energy ray curable pressure-sensitive adhesive composition is coated on a release sheet (the first release sheet) to have a predetermined thickness, and dried thereof to form the first coating film. Next, the pressure-sensitive adhesive sheet can be obtained by transferring the pressure-sensitive adhesive layer on the surface of the base.

In addition, in case of forming the pressure-sensitive adhesive layer by the cured product of energy ray curable pressure-sensitive adhesive composition, the first coating film is formed by coating the energy ray curable pressure-sensitive adhesive composition and drying thereof on the first release sheet. Next, the pressure-sensitive adhesive sheet can be obtained by transferring the first coating film on the surface of the base and curing thereof by the energy ray irradiation. Note, the pressure-sensitive adhesive layer can also be obtained by subjecting said energy ray irradiation to the first coating film on the release sheet, forming the pressure-sensitive adhesive layer, and transferring said pressure-sensitive adhesive layer on the surface of the base.

Ultraviolet rays are mentioned as the energy ray, and a near-ultraviolet including ultraviolet rays having a wavelength of 200 to 380 nm or so can be used. As the ultraviolet ray quantity (light quantity), it is generally 50 to 500 mJ/cm² or so, preferably 100 to 450 mJ/cm², and more preferably 200 to 400 mJ/cm². Further, ultraviolet ray illuminance is generally 50 to 500 mW/cm² or so, preferably 100 to 450 mW/cm², and more preferably 200 to 400 mW/cm². Ultraviolet ray source is not particularly limited, and a high pressure mercury lamp, a metal halide lamp, light emitting diode or so may be mentioned. In case when ultraviolet rays are used as the energy ray for irradiation hereinafter, similar with the above, suitable conditions can be selected from such range.

As release sheet, the film exemplified as the base mentioned above can be used.

Further, the composition for resin film formation is coated on the other release sheet (the second release sheet) forming the film for resin film formation. Subsequently, the other release sheet (the third release sheet) is laminated on the film for resin film formation, and a multilayered body of “the second release sheet/the film for resin film formation/the third release sheet” is obtained.

Next, the film for resin film formation is cut to have roughly the same shape as the work, which is attached to the film for resin film formation or the shape which can completely include the shape of the work, and residues are removed. In case when the multilayered body of “the second release sheet/the film for resin film formation/the third release sheet” has the belt shape, a plural number of the multilayered bodies of “the second release sheet/the film for resin film formation/the third release sheet” continuously held by the lengthy third release sheet can be obtained by leaving the third release sheet without cutting-in.

And the film for resin film formation is laminated on the pressure-sensitive adhesive layer of the pressure-sensitive adhesive sheet obtained above by releasing the second release sheet from the multilayered body of “the second release sheet/the film for resin film formation/the third release sheet”. Then, a multilayered body composed of the base/the pressure-sensitive adhesive layer/the film for resin film formation/the third release sheet is obtained. Subsequently, by removing the third release sheet, the composite sheet for resin film formation according to an aspect of FIG. 1 of the present invention.

### [The Production Method of the Semiconductor Device]

Next, the method of using the composite sheet for resin film of the present invention will be described using the case of applying said sheet for the production of the semiconductor device.

The first manufacturing method of the semiconductor device using the composite sheet for resin film formation according to the present invention is preferable to include the following steps of adhering the film for resin film formation of the sheet to the work, dicing the work to make the chips, fixing the film for resin film formation on either face of the pressure-sensitive adhesive sheet and releasing from the pressure-sensitive adhesive sheet, and placing the chips on the die pad part or the die placement part of the other chips via film for resin film formation.

The work may be various materials such as a silicon wafer, or it may be a compound semiconductor wafer such as galium arsenic, a glass substrate, a ceramic substrate, an organic material substrate such as FPC, metal materials such as precision parts or so. Hereinafter, an explanation will be provided taking an example that the semiconductor wafer is used as the work.

The formation of the circuit to the wafer surface can be carried out by various methods including the method conventionally used such as etching method, liftoff method or so. Next, the opposite face (the backside) of the circuit surface of the wafer is ground. The method of grinding is not particularly limited, and the known means using the grinder or so may be used. During the backside grinding, to the circuit face protecting the circuit of the surface, the pressure-sensitive adhesive sheet called surface protection sheet is adhered. The backside grinding is carried out by fixing the circuit face side of the wafer (that is the surface protection sheet side) to the chuck table or so, then grinding the backside which is the side not formed with the circuit. The thickness of the wafer after the grinding is not particularly limited; however, it is usually 50 to 500 μm or so.

Then, depending on the needs, the fracture layer caused during the backside grinding is removed. The removal of the fracture layer is done by chemical etching, plasma etching or so.

Subsequent to the circuit formation and the backside grinding, the film for resin film formation of the composite sheet for resin film formation is attached to the backside of the wafer. The attachment method is not particularly limited; and for instance, the backside of the semiconductor wafer is placed on the film for resin film formation of the composite sheet for resin film formation according to the invention, slightly pressing thereof, and the semiconductor wafer is fixed. The composite sheet for resin film formation is fixed to the jig such as the ring frame or so at the outer peripheral part of the composite sheet for resin film formation.

In case when the film for resin film formation does not cause tackiness at room temperature, the film can be suitably heated. The heating temperature is not particularly limited; however, it is preferably 40 to 80° C.

Next, the energy ray is irradiated to the film for resin film formation from the pressure-sensitive adhesive sheet side, the reactive double bond group of the binder component is subjected to reaction and curing, the cohesive strength of the film for resin film formation is increased, and the pressure-sensitive adhesiveness between the film for resin film formation and the adhesive sheet can be decreased. As the irradiated energy ray, the ultraviolet ray (UV) or the electron beam (EB) is mentioned, and ultraviolet ray is preferably used.

Subsequently, the semiconductor wafer is cut by a blade dicing method using dicing saw or a laser dicing method using the laser beam or so, and the semiconductor chips are obtained. The cutting depth when using dicing saw is the depth considering a total of the thickness of the semiconductor wafer and the thickness of the film for resin film formation and the wearing quantity of the dicing saw; and the film for resin film formation is also cut to the same size with the chips.

Note, the energy ray irradiation can be performed at any stage after the attachment of the semiconductor wafer and before the release (pickup) of the semiconductor chips; for instance, the irradiation may be performed after the dicing or after the expanding process mentioned below. Further, the energy ray irradiation can be divided to a multiple action.

Next, according to the need, a distance between semiconductor chips is increased and the pickup of the semiconductor device can be further easily performed when the composite sheet for resin film formation is expanded. At this time, displacement is generated between the film for resin film formation and the pressure-sensitive adhesive sheet. Thus, pressure-sensitive adhesiveness between the film for resin film formation and the pressure-sensitive adhesive sheet is decreased and the aptitude for the pickup of the semiconductor chip is increased. When the pickup of the semiconductor chip is performed in this way, the cut film for resin film formation can be fixed and remained on backside of the semiconductor chip, and released from the pressure-sensitive adhesive sheet.

Next, the semiconductor chip is placed on the die placement part, such as on the die pad part of the lead frame or on the die placement part such as different semiconductor chip (the lower stage chips) or so, via the film for resin film formation. The die placement part may be heated before the placement of the semiconductor chip, immediately after the placement of the semiconductor chip, or immediately after the placement of the chips. The heat temperature is generally 80 to 200° C., and preferably 100 to 180° C. The heat time is generally 0.1 sec. to 5 min. and preferably 0.5 sec. to 3 min. The pressure when the placement is performed is 1 kPa to 200 MPa.

After placing the semiconductor chip on the chip placement part, further heat treatment may be performed according to the need. The heating conditions thereof are: the heating temperature is in the abovementioned range and the heating time is generally 1 to 180 min., and more preferably 10 to 120 min.

Subsequently, the chips are sequentially laminated in a temporarily adhered manner. And after the wire bonding, the real curing may be performed to the film for resin film formation using the heat of resin sealing generally performed during the package manufacturing method. By passing through such steps, the film for resin film formation may be collectively cured, and the production efficiency of the semiconductor device is improved. Further, the wire bonding is stably performed since the film for resin film formation shows certain degree of hardness during said wire bonding. In addition, the film for resin film formation is softened under the die bonding conditions, thus, the film is sufficiently embedded in unevenness of the die placement part, and occurrence of voids can be prevented leading to improve the package reliability.

As the second manufacturing method of the semiconductor device, firstly, the groove is formed fitted to the outline of the separated semiconductor chip formation on the semiconductor wafer surface, a surface protective sheet is attached to the semiconductor wafer surface, subsequently the semiconductor wafer is separated to the semiconductor chips by grinding (thinning treatment) from the backside until reaches the groove. Namely, a plural number of chip groups obtained by said dicing before grinding method are prepared.

Subsequently, similar with the first manufacturing method, the composite sheet for resin film formation is fixed to the ring frame, and the backside of the chip groups is placed on the film for resin film formation of the composite sheet for resin film formation, slightly pressing thereof, and the chip groups are fixed. Subsequently, only the film for resin film formation is diced to the chip size. The method for only dicing the film for resin film formation is not particularly limited, and for instance, the laser dicing method can be used.

Subsequent steps of the expanding step of the composite sheet for resin film formation performed according to needs or the step of fixing and remaining the film for resin film formation on the semiconductor chip, releasing from the pressure-sensitive adhesive sheet, and adhering the semiconductor chip on the die placement part via the film for resin film formation, are as mentioned in the above first manufacturing method.

As the preferable third manufacturing method of the semiconductor device, the film for resin film formation of the composite sheet for resin film formation is adhered to the backside of the semiconductor wafer formed with the circuit on the surface, then obtaining semiconductor chip having the resin film on the backside. Said resin film is the protective film of the semiconductor chip. Also, the third manufacturing method of the semiconductor device preferably includes the following steps (1) to (3); and said steps (1) to (3) are performed in an arbitrary order.

Step (1): releasing the pressure-sensitive adhesive sheet, and the film for resin film formation or the resin film,

Step (2): obtaining the resin film by curing the film for resin film formation,

Step (3): dicing the semiconductor wafer, and the film for resin film formation or the resin film.

First, the film for resin film formation of the composite sheet for resin film formation is attached to the backside of the semiconductor wafer. Subsequently, steps (1) to (3) are performed in an arbitrary order. Details of these steps are mentioned in JP Patent Application Laid Open No. 2002-280329. As an example, the case of carrying out in the order of (1), (2) (3) will be described.

First, the film for resin film formation of the composite sheet for resin film formation is adhered to the backside of the semiconductor wafer to which the circuit is formed on the surface. Next, the pressure-sensitive adhesive sheet is released from the film for resin film formation, and the multilayered body of the semiconductor wafer and the film for resin film formation is obtained.

Next, the film for resin film formation is heat cured, and the resin film is formed on the entire face of the wafer. As a result, the resin film formed of cured resin is formed to the wafer backside; hence the strength is improved compared to the case of wafer alone, thereby the breakage when handling the thinned wafer can be reduced. Also, compared to the coating method wherein the coating solution for the resin film is directly coated or made into film to the backside of the wafer or chip, the thickness of the resin film has excellent uniformity.

Next, the multilayered body of the semiconductor wafer and the resin film is diced for each circuit formed on the wafer surface. The dicing is carried out by cutting the wafer and the resin film. The dicing of the wafer is carried out by usual method using the dicing sheet. As a result, the semiconductor chip group composing the resin film on the backside is obtained.

Lastly, by picking up the diced chip using the general means such as collet or so, the semiconductor chip composing the resin film on the backside is obtained. Further, the semiconductor device can be produced by mounting the semiconductor chip on the predetermined die placement part by face down method. According to the present invention as such, the resin film having highly uniform thickness can be easily formed on the chip backside, and the cracks caused during the dicing step or after the packaging becomes difficult to occur. Note, a laser marking process can be carried out to the film for resin film formation or the resin film. The laser marking process can be carried out before or after the step (2) in which the resin film is obtained by curing the film for resin film formation. In the step, the product number or so is marked to the surface of the film for resin film formation or the resin film by grinding off the surface of the film for resin film formation or the resin film by irradiating the laser beam.

Note that, in case the film for resin film formation of the composite sheet for resin film formation is adhered on the backside of the semiconductor wafer, and then the step (3) is done before step (1); in such case, the composite sheet for resin film formation can function as the dicing sheet. That is, it can be used as the sheet to support the semiconductor wafer during the dicing step.

### EXAMPLES

Herein below, the present invention will be described based on the examples; however it is not to be limited thereto. Note that, in the following Examples 1 to 5 and Comparative Examples 1 and 2, <the reliability evaluation (1)>, <the release strength measurement> and <the pick-up aptitude (1)> mentioned below were carried out. And in the following Examples 6 to 8 and Comparative Example 3, the following <the reliability evaluation (2)> and <the pick-up aptitude (2)> mentioned below were carried out.

### <The Reliability Evaluation (1)>

### (Manufacturing the Semiconductor Chip)

To the polished face of the silicon wafer finished with the dry polish (the diameter of 150 mm and the thickness of 75 μm), the composite sheet for resin film formation was adhered using the tape mounter (Adwill RAD-2500 made by Lintec Corporation), then fixed to the ring frame for wafer dicing. Next, it was diced into the chips having the size of 8 mm×8 mm using the dicing device (DFD651 made by DISCO Corporation), at a cut speed of 50 mm/sec., and a rotational speed of 30,000 rpm. The pressure-sensitive adhesive sheet is cut-in by 20 μm, which is the cut-in amount when dicing.

### (Manufacturing the Semiconductor Package)

The substrate (LN001E-001 PCB(Au)AUS303 made by Chino Giken Corp.) forming the circuit pattern on copper foil of the copper-clad laminated board (CCL-HL830 made by Mitsubishi Gas Chemical Company, Inc., thickness of the copper is 18 μm), and having the solder resist (PSR-4000 AUS303 made by Taiyo Ink Corp.) on the pattern is used. The chip on the composite sheet for resin film formation obtained above is taken away from the pressure-sensitive adhesive sheet together with the film for resin film formation and crimped to the substrate via the film for resin film formation at 120° C., 250 gf and 0.5 sec. Next, the other chip is taken away from the pressure-sensitive adhesive sheet together with the film for resin film formation, crimped to the chip on the substrate via the film for resin film formation under the same conditions; the substrate in which the chips are laminated in two stages.

Subsequently, the substrate mentioned above was sealed with sealing device (MPC-06M TriAl, Press made by Apic Yamada Corp.) by the mold resin (KE-1100AS3 made by Kyocera chemical corp.) making the total thickness of 400 μm under the conditions of 175° C., 7 MPa and 2 min. Next, mold resin was cured at 175° C. for 5 hours.

Subsequently, the sealed substrate was attached to the dicing tape (Adwill D-510T made by Lintec Corporation), diced into the size of 15 mm×15 mm using the dicing device (DFD651 made by DISCO Corporation), and the semiconductor package for the reliability evaluation was obtained.

### (Evaluation: IR Reflow Resistance Property)

The obtained semiconductor package was left for 168 hours at 85° C. and the relative humidity of 60% to allow absorbing the moisture, then IR reflow (Reflow furnace WL-15-20DNX made by Sagami-Rikou Co., Ltd.) of heating time of 1 minute at the pre-heat condition of 160° C. and the maximum temperature of 260° C. was carried out for three times. Next, the presence of lifting/peeling at bonding part and the presence of package crack were evaluated by the scanning ultrasonic flow detection device (Hye-Focus made by Hitachi Construction Machinery Co., Ltd.) and the cross-section observation using digital microscope (VHX-1000 made by Keyence Co.) by polishing the cross-section by the cross-section polisher (refine/polisher HV made by Refinetec Co.).

In case when the release of 0.5 mm or more is observed at the bonding part between the substrate and the semiconductor chip or at the bonding part between a semiconductor chip and the other semiconductor chip, it was decided to be released. 25 tests of the package were put and the number of the package in which release is not occurred was counted.

### <The Reliability Evaluation (2)>

### (Manufacturing the Semiconductor Chip)

To the polished face of the silicon wafer carried out with #2000 polish (the diameter of 150 mm and the thickness of 280 μm), the composite sheet for resin film formation was adhered while heating at 70° C., using the tape mounter (Adwill RAD-3600F/12 made by Lintec Corporation).

Next, the film for resin film formation was cured by heating for 2 hours at 130° C., diced into the size of 3 mm×3 mm using the dicing device (DFD651 made by DISCO Corporation), and obtained the semiconductor chip with the resin film for the reliability evaluation.

### (Evaluation: Moisture and Heat Resistance)

As conditions of the precondition assuming the mounting process of the semiconductor chip, the semiconductor chip with the resin film was baked at 125° C. for 20 hours, and the moisture was absorbed under a condition of 85° C., 85% RH for 168 hours. Immediately after taking out, they were put into IR reflow furnace of the pre-heat condition of 160° C. and the peak temperature of 260° C. for three times. After the precondition, 25 of said semiconductor chips with the resin film were placed in the thermal shock chamber (TSE-11-A made by ESPEC CORP.), and the cycle of maintaining for 10 minutes at −40° C. then maintaining 10 minutes at 125° C. were carried out for 1000 cycles.

Then, for the semiconductor chip with the resin film which was taken out of the thermal shock chamber, lifting/peeling or the presence of the crack at the bonding part between the chips and the resin film were observed by the scanning ultrasonic flow detection device (Hye-Focus made by Hitachi Construction Machinery Co., Ltd) and the cross section observation. 25 chips were put and the number of the chips with no lifting, peeling or crack was counted.

### <The Release Strength Measurement>

The composite sheet for resin film formation was cut to 100 mm×25 mm, then the film for resin film formation of the composite sheet for resin film formation and PVC board were sticked.

Next, according to the examples 4 and 5, and comparative example 2, the ultraviolet rays were irradiated from the base side of the composite sheet for resin film formation. Light quantity of the ultraviolet ray irradiation was 220 mJ/cm² and illuminance was 160 mW/cm². Note, this ultraviolet ray irradiation is a procedure assuming the followings. Considering examples 4 and 5, it was assumed to increase the cohesive strength by irradiating ultraviolet rays to the film for resin film formation. Considering comparative example 2, it was assumed to decrease the pressure-sensitive adhesiveness of the pressure-sensitive adhesive layer by a general method of the pressure-sensitive adhesive sheet composed of the energy ray curable pressure-sensitive adhesive composition, namely, energy ray irradiation. Further, considering examples 4 and 5, the measurement was carried out to the case with no ultraviolet ray irradiation on the composite sheet for resin film formation.

Subsequently, using a tensile testing machine (a universal tensile testing machine: Instron made by Shimadzu Corp., Ltd.), force required to release the interface of the pressure-sensitive adhesive sheet and the film for resin film formation is measured at 23° C., under 50% of relative humidity, with the release angle of 180° and the release rate of 300 mm/min; and it was determined to be release strength.

### <The Pick-Up Aptitude (1)>

To the polished face of the silicon wafer finished with the dry polish (the diameter of 150 mm and the thickness of 40 μm), the composite sheet for resin film formation was adhered using the tape mounter (Adwill RAD-2500 made by Lintec Corporation), then fixed to the ring frame for wafer dicing. Next, in examples 4 and 5 and comparative example 2, ultraviolet rays were irradiated from the base side of the composite sheet for resin film formation. Light quantity of the ultraviolet ray irradiation was 220 mJ/cm² and illuminance was 160 mW/cm². Note, this ultraviolet ray irradiation is a procedure assuming the followings. Considering examples 4 and 5, it was assumed to increase the cohesive strength by irradiating ultraviolet rays to the film for resin film formation. Considering comparative example 2, it was assumed to decrease the pressure-sensitive adhesiveness of the pressure-sensitive adhesive layer by a general method of the pressure-sensitive adhesive sheet composed of the energy ray curable pressure-sensitive adhesive composition, namely, energy ray irradiation. Further, considering examples 4 and 5, the measurement was carried out to the case with no ultraviolet ray irradiation on the composite sheet for resin film formation.

Next, the wafer was diced to 10 mm×10 mm at a cut speed of 20 mm/sec., a rotational speed of 50,000 rpm, and cut-in amount to the base of pressure-sensitive adhesive sheet of 20 μm, using the dicing device (DFD651 made by DISCO Corporation), and obtained chips. The presences of the chip fly during dicing were confirmed by visual observation.

Next, pickup of the chips was carried out using Die Bonder (BESTEM-D02 made by Canon Machinery Inc.) under the following conditions: the slider speed of 20 mm/sec., 30 mm/sec., 60 mm/sec. and 90 mm/sec., and the chips were placed on the substrate. Pickup success rate (%) of each slider speed was calculated with the following formula.

Pickup success rate (%)=(number of chips possible to pickup)/(number of chips tried to pickup)×100

Note, “number of chips possible to pickup” is the number of chips in which pickup failures (The device is stopped without picking out the chips or the chips are damaged.) are not generated and were placed on the substrate.

### (Pickup Condition)

Collet: Voidless type
Collet Size: 11 mm×11 mm
Pickup method: slider type (needleless type)
Slider width: 11 mm

### Expand: 3 mm

### <The Pick-Up Aptitude (2)>

To the polished face of the silicon wafer finished with the dry polish (the diameter of 150 mm and the thickness of 350 μm), the composite sheet for resin film formation was adhered using the tape mounter (Adwill RAD-2500 made by Lintec Corporation) while heating at 70° C. Further, the composite sheet for resin film formation was fixed to the ring frame for wafer dicing. Considering the composite sheet for resin film formation of comparative example 3, ultraviolet rays were irradiated from the base side of the composite sheet for resin film formation after attached to the silicon wafer. Light quantity of the ultraviolet ray irradiation was 220 mJ/cm² and illuminance was 160 nW/cm². This ultraviolet ray irradiation is a general method of the pressure-sensitive adhesive sheet composed of the energy ray curable pressure-sensitive adhesive composition, namely, it was assumed to decrease the pressure-sensitive adhesiveness of the pressure-sensitive adhesive layer by energy ray irradiation.

Next, the wafer was diced to 10 mm×10 mm at a cut speed of 20 mm/sec., a rotational speed of 50,000 rpm, and cut-in amount to the base of pressure-sensitive adhesive sheet of 20 μm, using the dicing device (DFD651 made by DISCO Corporation), and obtained chips. The presences of the chip fly during dicing were confirmed by visual observation.

Next, pickup of the chips was carried out using Die Bonder (BESTEM-D02 made by Canon Machinery Inc.) under the following condition: the slider speed of 90 mm/sec., and the chips were placed on the substrate. Pickup success rate (%) thereof was calculated with the following formula.

Pickup success rate (%)=(number of chips possible to pickup)/(number of chips tried to pickup)×100

Note, “number of chips possible to pickup” is the number of chips in which pickup failures (The device is stopped without picking out the chips or the chips are damaged.) are not generated and were placed on the substrate.

### (Pickup Condition)

Collet: Voidless type
Collet Size: 11 mm×11 mm
Pickup method: slider type (needleless type)
Slider width: 11 mm

### Expand: 3 mm

### EXAMPLES AND COMPARATIVE EXAMPLE

### Manufacturing Examples of the Pressure-Sensitive Adhesive Composition

Each component constituting the pressure-sensitive adhesive composition constituting the pressure-sensitive adhesive layer is described below and in Table 1. According to the following components and the compounding amount of Table 1, the pressure-sensitive adhesive composition was regulated by compounding each component. In table 1, numerical values of the each component are parts by mass in terms of the solid content. The solid content of the invention is a total component other than the solvent. In tables 2 and 3, the number of the crosslinkable functional group of crosslinking agent (B), with respect to the number of the reactive functional group of acrylic polymer (A1) or energy ray curable polymer (AD) is described as “equivalent of the crosslinking agent”.

(A) Polymer component
(A1-1) The acrylic polymer (Mw: 500,000, Tg: −58° C.) made by 95 parts by mass of butyl acrylate and 5 parts by mass of 2-hydroxyethyl acrylate,
(A1-2) The acrylic polymer (Mw: 700,000, Tg: −31° C.) made by 60 parts by mass of 2-ethylhexyl acrylate, 30 parts by mass of methyl methacrylate and 10 parts by mass of 2-hydroxyethyl acrylate, (AD) The energy ray curable polymer (Mw: 500,000, Tg: −27° C.) obtained by reacting the acrylic polymer made by 40 parts by mass of 2-ethylhexyl acrylate, 40 parts by mass of vinyl acetate and 20 parts by mass of 2-hydroxyethyl acrylate, and 5.3 g (80 moles with respect to 100 moles of 2-hydroxyethyl acrylate of the acrylic polymer) of methacryloyloxyethyl isocyanate with respect to 100 g of said acrylic polymer.
(B) Crosslinking agent: aromatic polyvalent isocyanate compounds (Coronate L made by Nippon Polyurethane Industry Co., Ltd., which was merged into Tosoh Corp.)
(C) Pasticizer: 1,2-cyclohexyl diisononyl carboxylate (DINCH made by BASF Japan Corp.)
(E) Potopolymerization initiator: 1-hydroxycyclohexyl phenyl ketone (Irgacure 184 made by Chiba Specialty Chemicals Co. Ltd., which was merged into BASF Japan)

As the release sheet, silicone releasing treated polyethylene terephthalate film (SP-PET381031, 38 μm thick made by Lintec Corporation) was prepared. Next, ethyl acetate solution (the solid concentration of 30 mass %) of the pressure-sensitive adhesive composition regulated with the compound amount described in Table 1 was coated on the surface subjected to silicone releasing treatment of the release sheet, dried for 2 minutes at 100° C., and formed the pressure-sensitive adhesive layer having the thickness of 10 μm.

Now, in examples Sand 8, and comparative example 1, ethyl acetate solution (the solid concentration of 30 mass %) of the energy ray curable pressure-sensitive adhesive composition was coated on the release sheet, dried thereof, ultraviolet ray irradiation (220 mW/cm², 160 mJ/cm²) was carried out as energy ray and the energy ray curable pressure-sensitive adhesive composition is cured forming the pressure-sensitive adhesive layer having the thickness of 10 μm.

Further, in comparative examples 2 and 3, ethyl acetate solution (the solid concentration of 30 mass %) of the energy ray curable pressure-sensitive adhesive composition was coated on the release sheet, dried thereof, and made the pressure-sensitive adhesive layer. The thickness was 10 μm.

Ethylene-methacrylic acid copolymer film (80 μm thick) on which electron beam is irradiated on one face is used as the base, the pressure-sensitive adhesive layer is transferred on electron beam irradiation surface, and the multilayered body in which the pressure-sensitive adhesive layer held between the release sheet and the base is obtained.

### Manufacturing Example of the Composition for Resin Film Formation

Each component of the composition for the resin film formation constituting the film for resin film formation is described below and in Table 1. According to the following components and the compounding amount of Table 1, the composition for resin film formation was regulated by compounding each component.

(F) The polymer component:
(F1-1) The acrylic polymer (Mw: 500,000, Mw/Mn=2.9, made by Toyo Chem. Co., Ltd.) made by 95 parts by mass of methyl acrylate and 5 parts by mass of 2-hydroxyethyl acrylate
(F1-2) The acrylic polymer (Mw: 400,000, Tg:7° C.) made by 1 part by mass of butyl acrylate, 79 parts by mass of methyl methacrylate, 5 parts by mass of glycidyl methacrylate and 15 parts by mass of 2-hydroxyethyl acrylate
(G) Heat curable component:
(G1) Acryloyl group added cresol novolak type epoxy resin (CAN-147 made by Nippon Kayaku Co., Ltd.)
(G1′-1) Phenol novolac type epoxy resin (EOCN-104S made by Nippon Kayaku Co., Ltd.)
(G1′-2) Bisphenol A type epoxy resin (epoxy equivalent of 180 to 200 g/eq)
(G1′-3) Dicyclopentadiene type epoxy resin (Epicron EP-7200HH made by DIC Corporation)
(G2′-1) Aralkylphenol resin (Mirex XLC-4L made by Mitsui Chemicals, Inc.)
(G2′-2) Dicyandiamide (ADEKA HARDNER 3636AS made by ADEKA Corporation)
(G3) 2-phenyl-4, 5-dihydroxymethylimidazol (CUREZOL 2PHZ made by SHIKOKU CHEMICALS CORPORATION)
(H-1) Filler: methacryloxy group modified silica filler (the average particle diameter of 0.05 μm made by Admatechs, 3-meta-cryloxy propyl trimethoxysilane treated product)
(H-2) Filler: untreated silica filler (molten quartz filler, the average particle diameter of 8 μm) (I) Coloring agent: Carbon black (MA650, the average particle diameter of 28 nm, made by Mitsui Chemicals, Inc.)
(J) The coupling agent: Silane coupling agent (MKC silicate MSEP2, made by Mitsui Chemicals, Inc.)
(K) Crosslinking agent: Aromatic polyvalent isocyanate compounds (Coronate L made by Nippon Polyurethane Industry Co., Ltd.)
(L) Photopolymerization initiator: 1-hydroxycyclohexyl phenyl ketone (Irgacure 184 made by Chiba Specialty Chemicals Co. Ltd., which was merged into BASF Japan)

As the release sheet, silicone releasing treated polyethylene terephthalate film (SP-PET381031, 38 μm thick, made by Lintec Corporation) was prepared. Next, the methyl ethyl ketone solution (20 mass % of the solid concentration) of the composition for resin film formation, regulated with the compound amount mentioned in Table 1, was coated on the surface of the release sheet subjected to silicone releasing treatment, dried thereof for 1 minute at 100° C., and the film for resin film formation of 20 μm thick was formed.

Then, the different release sheet was laminated on the film for resin film formation, and the multilayered body in which the film for resin film formation is held between release sheets is obtained.

Next, the abovementioned multilayered body is processed by punching a circular form having a diameter of 165 mm, and one release sheet and a circular peripheral part (remaining part) of the film for resin film formation is removed. Note, in order not to completely cut the other release sheet, punching work is carried out. Thus, the multilayered body in which the circular film for resin film formation is laminated on the release sheet (the other release sheet) was obtained.

Next, by releasing the release sheet of the multilayered body in which the pressure-sensitive adhesive layer is held between the release sheet and the base, the film for resin film formation and the pressure-sensitive adhesive layer were laminated, the multilayered body composed of “the release sheet/the film for resin film formation/the pressure-sensitive adhesive layer/the base” was obtained.

Lastly, the multilayered body mentioned above was punched concentrically with the film for resin film formation with a diameter of 207 mm, the release sheet was removed, and the composite sheet for resin film formation of FIG. 1 was obtained. Each evaluation results are shown in Tables 2 and 3.

TABLE 1

| | | Ex. | | | | | | | | Comp. Ex. | | |
|---|---|---|---|---|---|---|---|---|---|---|---|---|
| | | 1 | 2 | 3 | 4 | 5 | 6 | 7 | 8 | 1 | 2 | 3 |
| Pressure- | A1-1 | 100 | | 100 | 100 | | 100 | | | | | |
| sensitive | A1-2 | | 100 | | | | | 100 | | | | |
| Adhesive | AD | | | | | 100 | | | 100 | 100 | 100 | 100 |
| Composition | B | 20 | 10 | 20 | 20 | 10 | 20 | 20 | 10 | 10 | 10 | 10 |
| | C | 35 | | 35 | 35 | | 35 | | | | | |
| | E | | | | | 3 | | | 3 | 3 | 3 | 3 |
| Composition | F1-1 | 100 | 100 | 100 | 100 | 100 | | | | 100 | 100 | |
| for resin film | F1-2 | | | | | | 100 | 100 | 100 | | | 100 |
| formation | G1 | 30 | 30 | 30 | 30 | 30 | 100 | 100 | 100 | | 30 | 100 |
| | G1′ | | | | | | | | | 30 | | |
| | G2′ −1 | 6 | 6 | 6 | 6 | 6 | | | | 6 | 6 | |
| | G2′ −2 | | | | | | 2.4 | 2.4 | 2.4 | | | 2.4 |
| | G3 | | | | | | 2.4 | 2.4 | 2.4 | | | 2.4 |
| | H-1 | 35 | 35 | | 35 | 35 | | | | | | |
| | H-2 | | | | | | 325.2 | 325.2 | 325.2 | | | 325.2 |
| | I | | | | | | 10 | 10 | 10 | | | 10 |
| | J | 0.5 | 0.5 | 0.5 | 0.5 | 0.5 | 2 | 2 | 2 | 0.5 | 0.5 | 2 |
| | K | 1.5 | 1.5 | 1.5 | 1.5 | 1.5 | | | | 1.5 | 1.5 | |
| | L | | | | 1 | 1 | | | | | | |

TABLE 2

| | | Equivalent | The reliability | The release | The pick-up aptitude (1) | | | | |
|---|---|---|---|---|---|---|---|---|---|
| | | of the | evaluation (1) | strength | Presences | | | | |
| | | cross- | number with no | measurement | of the | Pickup success rate (%) | | | |
| | | linking | release/number | (mN/ | chip | 20 mm/ | 30 mm/ | 60 mm/ | 90 mm/ |
| | | agent | placed | 25 mm) | fly | sec. | sec. | sec. | sec. |
| Ex. 1 | | 2 | 25/25 | 93 | absence | 100 | 100 | 100 | 100 |
| Ex. 2 | | 1 | 25/25 | 86 | absence | 100 | 100 | 100 | 100 |
| Ex. 3 | | 2 | 12/25 | 91 | absence | 100 | 100 | 100 | 100 |
| Ex. 4 | No UV ray irradiation | 2 | 25/25 | 87 | absence | 100 | 100 | 100 | 100 |
| | UV ray irradiation | | 25/25 | 98 | absence | 100 | 100 | 100 | 100 |
| Ex. 5 | No UV ray irradiation | 1 | 25/25 | 108 | absence | 100 | 100 | 100 | 100 |
| | UV ray irradiation | | — | 341 | absence | 0 | 0 | 0 | 0 |

| | | | | | | | | |
|---|---|---|---|---|---|---|---|---|
| Comp. Ex. 1 | 1 | 0/25 | 86 | absence | 100 | 100 | 100 | 100 |
| Comp. Ex. 2 | 1 | Pickup failures | 540 | absence | 0 | 0 | 0 | 0 |

Note, “pickup failures” in the reliability evaluation (1) of Table 2 shows that the semiconductor package of the reliability evaluation was not able to pickup from the pressure-sensitive adhesive sheet, and was not able to evaluate.

TABLE 3

| | | The reliability | | |
|---|---|---|---|---|
| | | evaluation (2) | The pick-up aptitude (2) | |
| | Equivalent of | number with | | Pickup |
| | the cross- | no release/ | Presences of | success |
| | linking agent | number placed | the chip fly | rate (%) |
| Ex. 6 | 2 | 25/25 | absence | 100 |
| Ex. 7 | 1 | 25/25 | absence | 100 |
| Ex. 8 | 1 | 25/25 | absence | 100 |
| Comp. | 1 | Pickup failures | absence | 0 |
| Ex. 3 | | | | |

Note, “pickup failures” in the reliability evaluation (2) of Table 3 shows that the semiconductor package of the reliability evaluation was not able to pickup from the pressure-sensitive adhesive sheet, and was not able to evaluate.

1. A composite sheet for resin film formation comprising:
a pressure-sensitive adhesive sheet having a pressure-sensitive adhesive layer on a base and a heat curable film for resin film formation provided on the pressure-sensitive adhesive layer, wherein
the film for resin film formation includes a binder component having a reactive double bond group, and
the pressure-sensitive adhesive layer comprises a non-energy ray curable pressure-sensitive adhesive composition or a cured product of an energy ray curable pressure-sensitive adhesive composition.

2. The composite sheet for resin film formation as set forth in claim 1, wherein
the pressure-sensitive adhesive layer comprises the non-energy ray curable pressure-sensitive adhesive composition,
the non-energy ray curable pressure-sensitive adhesive composition comprises a polymer having a reactive functional group and a crosslinking agent, and
a crosslinkable functional group included in the crosslinking agent is 1 equivalent or more relative to the reactive functional group.

3. The composite sheet for resin film formation as set forth in claim 2, wherein the non-energy ray curable pressure-sensitive composition further comprises a plasticizer.

4. The composite sheet for resin film formation as set forth in claim 2, wherein the polymer having the reactive functional group is an acrylic polymer having a glass transition temperature in a range of −45 to 0° C.

5. The composite sheet for resin film formation as set forth in claim 1, wherein the film for resin film formation further includes a filler on which the surface thereof is modified by a compound having a reactive double bond group.

6. The composite sheet for resin film formation as set forth in claim 1, wherein the film for resin film formation is a die bonding adhesive film adhering a semiconductor chip to a die placement part.

7. The composite sheet for resin film formation as set forth in claim 1, wherein the film for resin film formation is a film for protective film formation which forms a film protecting backside of a face-down type semiconductor chip.
